(19) United States
(12) Patent Application Publication
(10) Pub. No.: US 2026/0112413 A1
(43) Pub. Date: Apr. 23, 2026

(54) MULTI-LEVEL NON-VOLATILE RESISTIVE DEVICE WITH WRITE-VERIFY ALGORITHM

(71) Applicants: Guoxing MIAO, Waterloo (CA); Manoj SACHDEV, Waterloo (CA); Rabiul ISLAM, Waterloo (CA); Yu SHI, Waterloo (CA)

(72) Inventors: Guoxing MIAO, Waterloo (CA); Manoj SACHDEV, Waterloo (CA); Rabiul ISLAM, Waterloo (CA); Yu SHI, Waterloo (CA)

(21) Appl. No.: 19/262,968

(22) Filed: Jul. 8, 2025

Related U.S. Application Data
(60) Provisional application No. 63/669,417, filed on Jul. 10, 2024.

(51) Int. Cl. G11C 13/00; H10N 70/00

(52) U.S. Cl. CPC G11C 13/0069; G11C 13/0007; G11C 13/004; G11C 13/0061; G11C 13/0064; H10N 70/841; H10N 70/8833; G11C 2013/0045; G11C 2013/0078

(57) ABSTRACT

A resistive memory device configurable to operate in either a volatile or a non-volatile memory modes. The device includes top and bottom electrodes with a lithium imbued TiOx switching layer in between, and in the volatile mode can have LRS or HRS states. The decay time scale is electrically and physically tunable. Electroforming permanently configures the volatile device into non-volatile mode. In the non-volatile memory mode, a state-aware write verify (SAW) algorithm based on the logarithmic time dependence of RESET is used, which provides a feedback mechanism to tune the time duration of write pulse during multi-level programming. The time duration is dependent on the read current difference between current resistance state and target resistance state, therefore, the desired time duration of write pulse for specific target resistance states can be deterministically calculated (read current difference is measured with verify operation). This eliminates the number of intermediate-verify steps needed.

### CROSS-REFERENCE TO RELATED APPLICATIONS

This application claims the benefit of priority of U.S. Provisional Patent Application No. 63/669,417 filed Jul. 10, 2024, which is incorporated herein by reference.

### FIELD

The present disclosure relates generally to resistive random access memory (RRAM). More particularly, the present disclosure relates to resistive memory devices and write-verify algorithms for RRAM.

### BACKGROUND

As a result of the remarkable advancements in artificial intelligence (AI), the Internet of Things (IoT), and big data technologies, a variety of intricate challenges including image and voice recognition, autonomous driving, and natural language processing, have been addressed through the utilization of the prevailing von Neumann architecture. However, this architecture is plagued by higher energy consumption and latency, as the memory and processor are physically segregated. To address this issue, researchers have proposed the adoption of neuromorphic computing (NC) architectures inspired by the human brain, in which the memory and processing elements are co-located, thereby eliminating the energy cost and latency of data shuffling.

Among various artificial neural network (ANN) architectures based on SRAM, DRAM, and memristor, the memristor-based ANN has been extensively studied due to its simple fabrication process and low integration cost. Furthermore memristors can have volatile or nonvolatile natures, resembling the short-term and long-term memory of the biological brain. In terms of ANN architectures, feedforward neural networks (FFNN) are particularly useful for static spatial patterns, such as image recognition, while recurrent neural networks (RNN) are more practical for dynamic data, including voice recognition and forecasting. RNN requires less number of training parameters compared to the FFNN network, thus reducing complexity. However, the training of RNNs suffers from a vanishing gradient problem. In a recurrent neural network, weight matrices are multiplied both in forward and backward propagation. When the error is multiplied and back propagated, there is a possibility that weights become weaker, known as the vanishing gradient problem. This phenomenon is more pronounced when the time sequence is large as the error is multiplied again and again, which reduces the value close to zero. Vanishing gradients problem results in incapability to decide which direction to move to minimize the loss function.

To solve this issue, a Reservoir Computing (RC) method was introduced where training updates only at the output layer, thus bypassing the interior complexity and reducing the number of training parameters. There are two main parts in the RC scheme: a reservoir layer and an output layer. The volatile memristors can act as a reservoir of the RC system, whereas the output layer can benefit from non-volatile elements to retain the training weights.

Some of the existing volatile memories are digital, meaning they set a certain threshold voltage to trigger the conductance change, and they cannot emulate the analog brain functionalities though still good in selector applications and artificial nociceptors. Recently, some researchers have shown analog-type memristor devices, where the conductance can be gradually tuned, thus emulating a biological synapse.

RC systems using memristors have been demonstrated by Midya, R.; Wang, Z.; Asapu, S.; Zhang, X.; Rao, M.; Song, W.; Zhuo, Y.; Upadhyay, N.; Xia, Q.; Yang, J. J. Reservoir computing using diffusive memristors. Advanced Intelligent Systems 2019, 1, 1900084; Moon, J.; Ma, W.; Shin, J. H.; Cai, F.; Du, C.; Lee, S. H.; Lu, W. D. Temporal data classification and forecasting using a memristor-based reservoir computing system. Nature Electronics 2019, 2, 480-487; and Zhong, Y.; Tang, J.; Li, X.; Gao, B.; Qian, H.; Wu, H. Dynamic memristor-based reservoir computing for high-efficiency temporal signal processing. Nature communications 2021, 12, 408.

Rivu Midya et al. demonstrated an RC system to classify the Modified National Institute of Standards and Technology (MNIST) handwritten digits database with diffusive memristors (Pt/SiO₂:Ag/Pd) and drift memristors (Ta/Ta₂O₅/Pd), even though the accuracy of the implementation was 83%. John Moon et al. performed classification and forecasting of temporal data using W/WOₓ/Pd/Au volatile memristor, and a parallel dynamic RC system was investigated by Yanan Zhong et al. using Pt/TaO_{y}/TiOₓ/Ti volatile memristors. In the above-mentioned works, the output layer was trained separately or using a different set of memristors.

Implementations of RC systems were realized by fabricating separate devices for reservoir and output layer respectively, as the reservoir layer needs highly nonlinear and dynamic system, for which volatile memory was utilized, and the output layer needs to retain training weights for a long time, for which non-volatile memory was used. As the devices' materials stack are different, different memory devices are required, hence the fabrication cost of the devices was expensive, they required larger areas and/or additional metal layers, and possibly different supporting circuitry that further increases complexity and cost.

Therefore, it is desirable to develop a universal memristor that can be configured as either volatile or non-volatile, to reduce footprints and latency in the memristor-based RC system. This would also allow one to realize low-cost RC systems with customizable layouts on the same platform of memristors.

Non-volatile RRAM is also advantageously used in Compute-In-Memory (CIM) systems. In traditional accelerators based on Von Neumann architecture, frequent data movements are needed between the processing units and the memory units, which increases the delay and energy consumption. To minimize the energy and time budget in data shuffling, CIM has been proposed to execute computation inside memory in forms like accelerating matrix operation using the analog properties of memory cells. Compared to SRAM or DRAM based CIM, RRAM based CIM shows its advantages in multibit capability and energy efficiency owing to its non-volatile memristor nature.

While a non-volatile analog-type memristor device functions similar to a multi-bit non-volatile cell, by storing different conductance levels, the proper level for each memory device must be verified after writing (programming). This is done through a write-verify process which cannot be avoided.

Prior work on RRAM-based CIM program cells use iterative write-verify algorithm. However, with the number of parameters in most state-of-the-art Al models exceeding 100M, simply scaling up macro size would suffer from yield issues and it would take hours to program mega-bit sized CIM macro due to the write variations of RRAM devices.

Therefore, it is further desirable to optimize the conventional write verify algorithm for multi-level programming to save programming time without compromising the computing performance.

### SUMMARY

It is an object of the present disclosure to obviate or mitigate at least one disadvantage of previous resistive memory devices.

In a first aspect, the present disclosure provides a resistive memory device configurable to operate in volatile or non-volatile modes. The resistive memory device includes a first electrode, a switching layer and a second electrode. The switching layer includes lithium imbued TiOx or other combination of ion-active metal/metalloid compounds coupled with the controllable embedment/extraction of ions including cations like hydrogen/alkaline/alkaline-earth/transition-metal ions and anions like halogen/chalcogen/pnictogen ions, having a first end electrically coupled to the first electrode and electrically configurable to have at least a high resistance state (HRS) and a low resistance state (LRS). The second electrode is electrically coupled to a second end of the switching layer and configured to receive a gradually increasing positive DC voltage to set the switching layer from HRS to LRS in the volatile mode, wherein application of voltage and current across the first electrode and the second electrode electroform conductive filaments in the lithium imbued TiOx to set the non-volatile mode. Here an applied positive DC voltage sets the HRS to LRS in the non-volatile mode, and an applied negative DC voltage opposite to the positive DC voltage resets the LRS to HRS in the non-volatile mode.

According to an embodiment of the first aspect, the switching layer is configured to have an intermediate state between HRS and LRS in response to a different negative DC voltage. According to another embodiment of the first aspect, a time scale of a volatile change is electrically tunable with applied voltages and voltage application time, or physically with diffusion barrier insertion and/or ion channel constriction, between the ion reservoir and the ion active layer.

In a second aspect, the present disclosure provides a write-verify method for a multi-level resistive memory device. The method includes a) measuring a resistance state of the memory device to obtain a read current; b) determining a current write operation to be either a SET operation or a RESET operation by comparing the read current to a target current corresponding to a logic level; c) determining a write time for a current RESET operation based on a logarithmic time dependence of RESET in response to the read current and write time of a previous RESET operation, where the write time for a current SET operation is fixed; d) executing the current RESET operation with a RESET voltage when the write direction is for the RESET operation, or a current SET operation with a SET voltage when the write direction is for the SET operation; e) determining if the current write operation differs from a previous write operation, and reducing the SET voltage and the RESET voltage by a first predetermined amount if the current write operation is not the same as the previous write operation, or increasing the SET voltage and the RESET voltage by a second predetermined amount if the current write operation is the same as the previous write operation; and f) iteratively repeating steps a)-e) until the read current is approximately the target current, or when a predetermined number of iterations of steps a)-e) is reached, and also ensure the last step is RESET terminated for reducing short-term relaxation.

In a third aspect, the present disclosure provides an optional electrical annealing method for improving retention of conductance states programmed by the above described write-verify methods, by applying a predetermined number of voltage pulses each having a predetermined amplitude effective for locally heating formed filament regions without global temperature increases.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1(a) is a schematic of the dual volatile and non-volatile device structure, according to a present embodiment;

FIG. 1(b) is an SEM image of a device lamella profile prepared by FIB showing all layers on the sidewall profile of a fabricated dual volatile and non-volatile device;

FIG. 1(c) is a cross-sectional STEM micrograph of the fabricated dual volatile and non-volatile device with a zoomed-in TEM image showing several layers present on the device;

FIG. 2(a) is a plot showing gradual change in I-V characteristics of the device upon sweeping five full voltage loops;

FIG. 2(b) is a plot of conductance changes as a function of sweep delay between applied voltage for the device;

FIG. 2(c) is a plot of change in conductivity as a function of increasing voltage for the device;

FIG. 2(d) is a plot of gradual increase in conductance upon the applications of five consecutive positive sweep (0V−(+2V)−0V) and decrease in conductance upon the applications of five consecutive negative sweep (0V−(−2V)−0V) for the device;

FIG. 3 is a diagram showing the analogy between biological synapse and Li-ion imbued TiOx synapse of the present embodiment;

FIG. 4(a) is a plot of I-V characteristics of ten 4 μm×4 μm and ten 10 μm×10 μm devices;

FIG. 4(b) is a plot I-V characteristics of the device with asymmetric voltage sweep to show endurance of the device;

FIG. 4(c) is a plot showing current-voltage characteristics of 50 volatile devices distributed across 1 cm-by-1 cm area;

FIG. 5 is a plot showing self-relaxation and voltage-assisted relaxation from the device;

FIG. 6 is a plot showing I-V characteristics comparison of different control devices before forming, where the switching layers have the same thickness;

FIG. 7(a) is a plot showing the device response upon varying pulse amplitude;

FIG. 7(b) is a plot showing device current upon varying pulse delay;

FIG. 7(c) is a plot showing continuous bias and its corresponding conductance (Inset shows the conductance decay at different excitation durations);

FIG. 7(d) is a plot showing Potentiation and Depression characteristics from the device upon the application of positive and negative voltage pulses;

FIG. 7(e) is a plot showing partial conductance decay when the pulse delay is 15 ms;

FIG. 7(f) is a plot showing power-law fitting result of the conductance decay as a function of excitation duration;

FIG. 8(a) is a plot showing temperature-dependent current-voltage characteristics;

FIG. 8(b) is a plot showing resistance value at +1V for two different sweep conditions: one at up sweep and another is down sweep;

FIG. 8(c) is a plot showing relative values of the current changes at different temperatures @+1V;

FIG. 9(a) is a plot showing the activation energy barrier slope above transition temperature;

FIG. 9(b) is a plot showing the activation energy barrier slope below transition temperature;

FIG. 9(c) is an illustration of O-defective structure of anatase TiO₂ using ionic radii style showing the Li migration pathway;

FIG. 9(d) is a plot showing the energy barrier profile for Li migration obtained from DFT-NEB calculations, showing a barrier of 0.4 eV;

FIG. 9(e) is a plot showing constant-voltage stress at different temperatures with an applied voltage of +1V;

FIG. 10(a) is plot showing the forming process comparison of TiOx and Li-imbued TiOx memory devices;

FIG. 10(b) is plot showing multi-state capability of the device when stopped at different RESET stop voltages (Vs);

FIG. 10(c) is plot showing retention characteristics of the device after applying an incremental reset voltage sweep to set 32 different states;

FIG. 10(d) is plot showing retention behavior of 16 states from the device;

FIG. 11(a) illustrates a process flow of RC for voice recognition;

FIG. 11(b) is a cochleagram of voice data, binarized data, and RC processed data;

FIG. 11(c) is a plot showing voltage input of channel #30 and corresponding current of volatile device at time scale;

FIG. 11(d) is a graphical comparison of classification accuracy between quantized RC model, RC model and model without RC processing;

FIG. 12 is a schematic of a 2T2R CIM array, according to a present embodiment;

FIG. 13(a) is a schematic of the device structure, according to a present embodiment;

FIG. 13(b) is a cross section STEM image of the fabricated devices of the present embodiment;

FIG. 13(c) is a plot of I-V characteristic of FORMING I-V characteristic of FORMING (circles) and bipolar switching (triangles) of fabricated devices;

FIG. 13(d) is a plot of I-V characteristic of RESET with different stop voltages;

FIG. 13(e) is a plot of a retention test of resistance state at varied RESET stop voltage (read voltage: −0.2 V);

FIG. 14(a) is a plot showing current transient of RESET under different voltage biases;

FIG. 14(b) is a plot showing different write times for the same bias voltage but with RESET pulses having varied durations;

FIG. 14(c) is a plot showing different initial resistance states;

FIG. 14(d) is a plot showing the proposed state-aware RESET write time calculation, according to a present embodiment;

FIG. 15 is a flow chart of a write-verify algorithm for multi-bit encoding, according to a present embodiment;

FIG. 16(a) is a plot showing an example of state oscillation between the target value and automatic adjustment of SET/REST voltage;

FIG. 16(b) is a chart comparing total write time for 4-bit encoding between the state aware write-verify (SAW) algorithm of the present embodiment and prior art incremental step pulse programming algorithm;

FIG. 16(c) is a plot of the distribution probability of 4-bit resistance states across devices;

FIG. 16(d) is a plot of the cumulative probability of 4-bit resistance states across devices;

FIG. 17(a) is a plot of Conductance change (AG) versus pulse time;

FIG. 17(b) is a plot of Conductance change ratio versus the pulse amplitude;

FIG. 17(c) is a plot of Conductance change versus the initial conductance;

FIG. 18(a) is a flow chart of a state aware write verify (SAW) algorithm, according to a present embodiment;

FIG. 18(b) is a flow chart of the status flag update algorithm, according to a present embodiment;

FIG. 18(c) is a flow chart of the RESET voltage and time calculation module, according to a present embodiment;

FIG. 18(d) shows an example programming process;

FIG. 19 shows a sequence for electrical annealing, according to a present embodiment;

FIG. 20(a) shows experimental retention results of programmed conductance states without electrical annealing;

FIG. 20(b) shows experimental retention results of programmed conductance states with electrical annealing.

### DETAILED DESCRIPTION

Unless defined otherwise, all technical and scientific terms used herein have the same meaning as commonly understood by one of ordinary skill in the art to which this invention belongs.

As used herein, the term “about” refers to an approximately +/−10% variation from a given value. It is to be understood that such a variation is always included in any given value provided herein, whether or not it is specifically referred to.

The term “plurality” as used herein means more than one, for example, two or more, three or more, four or more, and the like.

The use of the word “a” or “an” when used herein in conjunction with the term “comprising” may mean “one”, but it is also consistent with the meaning of “one or more”, “at least one”, and “one or more than one”.

As used herein, the terms “comprising”, “having”, “including”, and “containing”, and grammatical variations thereof, are inclusive or open-ended and do not exclude additional, unrecited elements and/or method steps. The term “consisting essentially of” when used herein in connection with an apparatus, system, composition, use or method, denotes that additional elements and/or method steps may be present, but that these additions do not materially affect the manner in which the recited apparatus, system composition, method or use functions. The term “consisting of” when used herein in connection with an apparatus, system, composition, use or method, excludes the presence of additional elements and/or method steps. An apparatus, system composition, use or method described herein as comprising certain elements and/or steps may also, in certain embodiments consist essentially of those elements and/or steps, and in other embodiments consist of those elements and/or steps, whether or not these embodiments are specifically referred to.

The present embodiments describe a resistive memory device that can be configured in volatile as well as non-volatile memory modes. This is in contrast to existing technologies which require two different material stacks to realize each of the volatile and non-volatile operational modes.

The resistive memory device according to the present embodiment consists of a top and bottom electrode and Lithium imbued TiOx as a switching layer. In the volatile memory operation mode, the device is initially in low conductance state (high resistance state [HRS], representing logic “0”) and upon the application of gradually increasing positive DC voltage at top electrode, the conductance can be altered to high conductance value (low resistance state [LRS], representing logic “1”). However, upon the removal of Voltage bias, the LRS can be returned to HRS within a tunable timeframe upon the removal of bias.

For reading of the LRS state (or memory state), a smaller (less than the DC voltage required to program the memory) positive or negative voltage is applied to the top electrode which will cause a DC current to flow through the memory cell which can be sensed by a circuit. If the device was set to HRS, then this applied read voltage applied to the top electrode will not be sufficient to cause the DC current flow. The choice of sensing voltage also influences the time constant of the conductivity decay process.

Advantageously, the same volatile resistive memory device can be configured into a non-volatile one after an electroforming process. The SET process, which changes the HRS to LRS (“0” to “1”), can be achieved by applying positive DC voltage at top electrode. The RESET process, which changes the LRS to HRS (“1” to “0”), can be achieved at opposite polarity.

In addition, the non-volatile resistive memory device can store multiple bits of information when stopped at appropriate RESET voltages. Moreover, non-volatile memory states can be deterministically written by a state-aware write-verify (SAW) algorithm for high-capacity information and training weight storage per device. The SAW algorithm is discussed later after the dual volatile and non-volatile resistive memory device is described.

The dual volatile and non-volatile resistive memory device of the present embodiment is CMOS compatible. This resistive memory device consisting of TiOx, which is known as a good cathode material, and Lithium Phosphorous Oxynitrate (LiPON), a good solid state Li electrolyte, together form a device capable of controllable ionic motion under applied voltages, and configurable to either volatile or non-volatile behavior. Volatile memory characteristics can be obtained without needing device forming or compliance currents, thus obviating complex setups.

### A Pulse-Dependent Study Revealed Short-Term Plasticity

(STP), where conductance gradually varies with the application of short-duration pulses. A temperature-dependent conduction study shows a sharp change in conductance above a threshold temperature of 220K. In contrast, below the threshold temperature, the ion displacement-mediated conductance gives way to weakly temperature-dependent variable range hopping conduction. After electroforming, i.e., creating conductive filaments, these devices can also be configured for non-volatile memory applications with good retention and endurance. Thus, both volatile and non-volatile properties can be obtained on the same memristor-based neuromorphic computing chips, a desirable platform for creating non-von Neumann architectures. In experiments, the device characteristics were applied to a model task of voice recognition, showing excellent accuracy of about 97.2% with a minimal amount of training data input.

The dual volatile and non-volatile resistive memory device material and structure are now described.

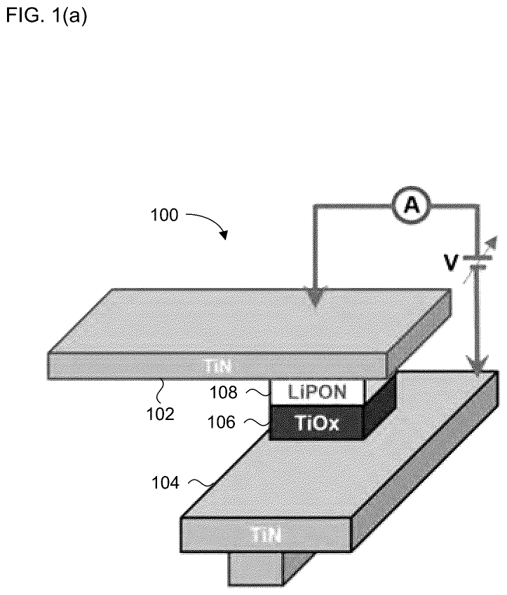

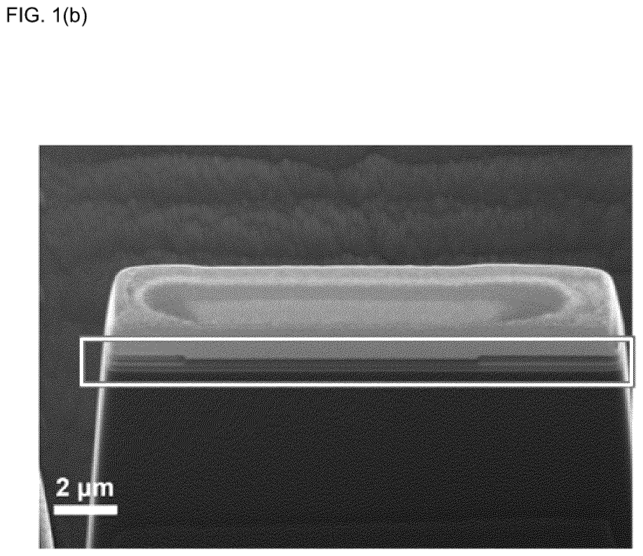

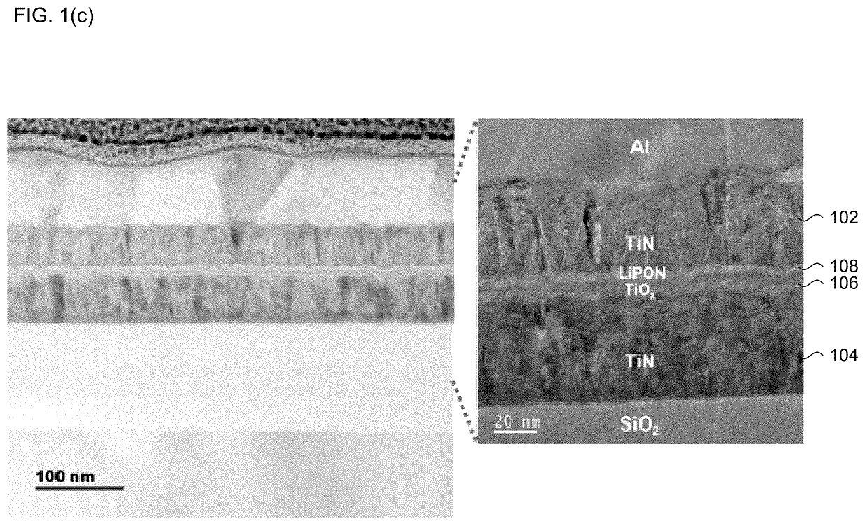

A schematic of the device structure according to the present embodiment, consisting of two TiN layers as top and bottom electrodes, and a TiOx and LiPON bilayer as the active switching layer, is shown in FIG. 1(a).

The dual volatile and non-volatile resistive memory device 100 shown in FIG. 1(a) includes a top electrode 102, a bottom electrode 104 and an active switching layer composed of a layer of TiOx 106 and a layer of LiPON 108. The top electrode 102 is connected to the source whereas the bottom electrode 104 is grounded. FIG. 1(b) is an SEM image showing a lamella with the cross-sectional focused ion beam scanning electron microscopy (FIBSEM) overview of the device layers, which are processed for transmission electron microscope (TEM) analysis. This image shows all layers on the sidewall profile. The region of interest is shown with a white rectangular box and the active region (thinner part in the middle) is surrounded by side walls of SiO₂ passivation.

In the cross-sectional TEM images (with zoomed in TEM image), shown in FIG. 1(c), the different material layers are contrasted (from bottom to top, SiO₂ on the substrate, TiN of 50 nm, TiOx of 8 nm, LiPON of 4 nm, TiN of 45 nm, Al of 70 nm). Both the top and bottom TiN electrodes 102 and 104 are polycrystalline, whereas TiOx 106 and LiPON 108 do not show any visible crystallinity, reflecting an amorphous nature.

The stated thicknesses for the different material layers represents one possible embodiment for the device. Possible ranges for the materials are as follows: TiN: 30 to 50 nm; TiOx: 4 nm to 16 nm; LiPON: 3.5 nm to 6 nm; TiN: 30 to 50 nm; Al: 30 to 100 nm. Therefore many combinations of these materials with differing thicknesses can be used to form alternate embodiments. It is noted that the thickness of TiN or Al electrodes is not critical, and the ion responsive layer TiOx (or similar) can be as thick as microns or as thin as sub nm, as long as its conductivity changes with ion insertion. Similarly, the ion reservoir layer (LiPON or similar) can also range from microns to sub nm, as long as it provides sufficient ions. Alternatively, an actual anode layer (Li or similar) can be used as the ion source with its thickness determined by the number of ion intercalation needed (which determines the depth of ion manipulation to be achieved). For example, TiOx/LiPON/Li, where TiOx is the active layer/cathode, LiPON is the electrolyte, Li is the anode. When Li (or other ion source) is both the electrode and ion source, its thickness is relevant. Thicknesses beyond microns are still possible, creating larger conductivity changes at the sacrifice of the device's operation speed.

This dual volatile and non-volatile resistive memory device can be fabricated using a standard CMOS process. According to a present embodiment, the following CMOS fabrication steps can be executed to manufacture the presently described and characterized dual volatile and non-volatile resistive memory device.

Three-inch Si wafers with thermally grown 100 nm SiO₂ were used as the substrates. After finishing the cleaning process, the TiN bottom electrode 104 was deposited using DC sputtering. It is then patterned with standard photolithography processes and etched using ion milling with a secondary ion mass spectroscopy (SIMS) to detect the end-point. Next, a 60 nm SiO₂ passivation layer was deposited using the plasma-enhanced chemical vapor deposition (PECVD) process. Then the sample was again patterned using photolithography and the SiO₂ layer was etched using reactive ion etching (RIE) to open active areas of the devices. Another lithography and liftoff step defined the switching layer and the top electrode 102 (TiN/Al) and formed junctions with the bottom electrode through the active openings. The LiPON 108 and TiOx 106 were reactively sputtered by properly adding N₂ and O₂ gases, respectively.

Following is a discussion of the DC characteristics of the dual volatile and non-volatile resistive memory device of the present embodiment, referred to simply as the device for brevity.

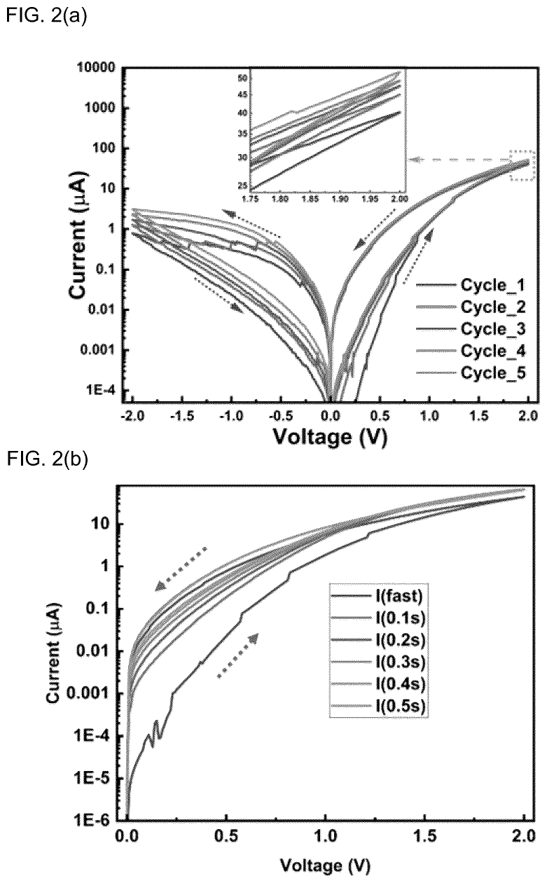

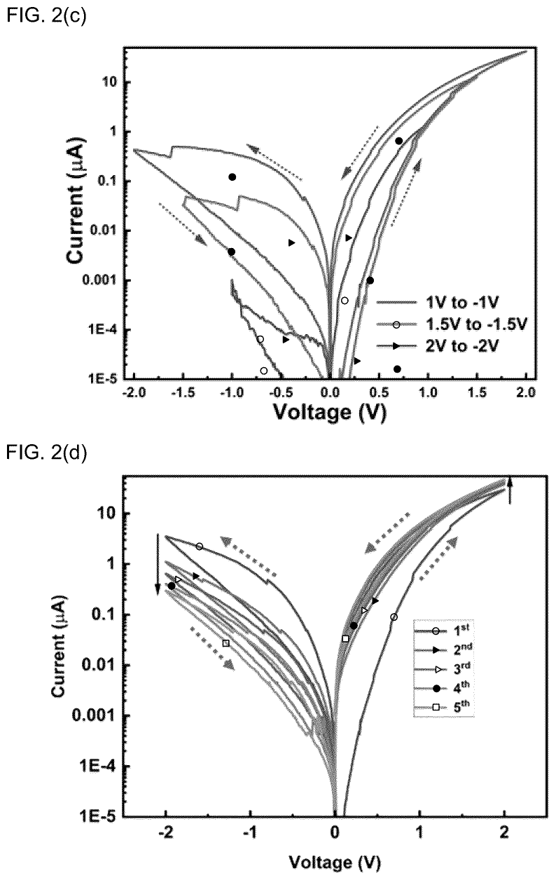

Upon the application of linearly sweeping voltages, the device shows a hysteresis loop, meaning that there is a volatile resistive switching from a high resistance state (HRS) to a low resistance state (LRS) at a positive polarity and from LRS to HRS at opposite polarity, as shown in FIG. 2(a). More specifically, FIG. 2(a) shows a gradual change in I-V characteristics of the device upon sweeping five full voltage loops. The conductance modulation is also a function of sweep speed, as demonstrated in FIG. 2(b). As the speed decreases, the ratio of the conductance modulation becomes smaller due to self-relaxation. The reversed rotation in opposite polarities is a clear indication that the volatile conductance change is not from trivial mechanisms such as parasitic capacitance. The inset of FIG. 2(a) shows that repeatedly sweeping full voltage loops increases the overall conductance.

The device's conductance also depends on the amplitude of the applied biases. FIG. 2(c) illustrates the change in the conductance with different amplitudes of voltage biases. This indicates that with a higher applied voltage, more ions can enter and depart the TiOx layer and alter the conductance more. When the voltages sweep only in one polarity (half loops), the devices' conductance increases after consecutive positive sweeps and decreases after consecutive negative voltage sweeps, as shown in FIG. 2(d).

With repeated positive potentials, more Li-ion can migrate into the TiOx layer and create defects, causing the increase in conductance; and repeated negative potentials do the opposite by depleting ions. This gradual change in conductance is analogous to the efficacy modulation in biological synapses upon the application of the repeated stimulus. Thus, Li-ion modulated TiOx, before forming, exhibits gradual and volatile conductance modulation and can be used for artificial synapses.

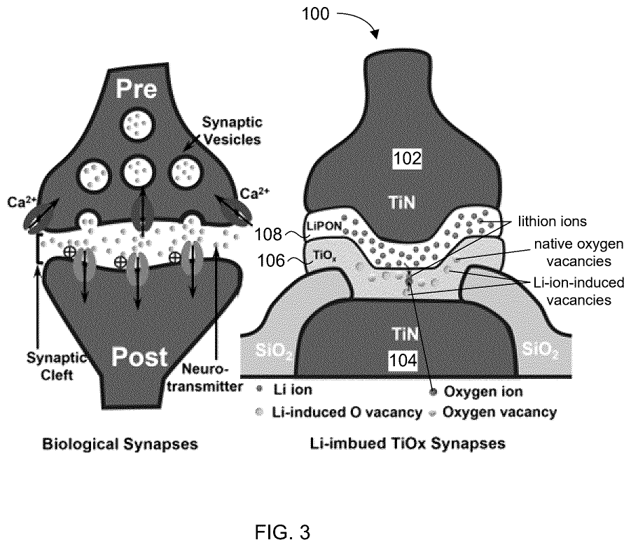

FIG. 3 is a diagram showing the analogy between biological synapse and Li-ion imbued TiOx synapse based on a present embodiment of the device shown in FIG. 1(a), where the same reference numbers designate the same structures shown in FIG. 1(a). Here Li-induces oxygen vacancies are created due to the migration of Li-ion into TiOx layer, which then forms a bond with oxygen atom, leaving the TiOx more oxygen deficient (reducing the local x). When an action potential is generated at the presynaptic neuron terminal or axon, voltage-gated Calcium channels trigger and Calcium ions (Ca²⁺) start flowing into the presynaptic neuron and synaptic vesicles shift towards the synaptic cleft and release neurotransmitters, which then bind to receptor proteins across the gap and cause Na or K ions to conduct through the post-synaptic neuron, and this process strengthens or weakens the connection strength between synapses.

Similarly, in Li-imbued TiOx devices, under positive applied bias, lithium ions (red spheres) can migrate into the TiOx layer as shown in FIG. 3. Here, the yellow spheres represent Li-ion-induced vacancies, and the gray ones are native oxygen vacancies already in TiOx. Li ions preferably combine with oxygen and chemically reduce Ti, which has similar effects as forming oxygen defects in TiOx (reducing x). Therefore, the Li-ion insertion/extraction increases/decreases the device conductivity accordingly. Li migration is similar to oxygen migration but it is much easier and happens readily at room temperature and low current densities, i.e., no set/reset voltages/currents or current induces hotspots are needed. The current amplitude can vary well over an order of magnitude in these processes, depending on the history. The devices therefore possess history-dependent volatile memory suitable for neuromorphic applications.

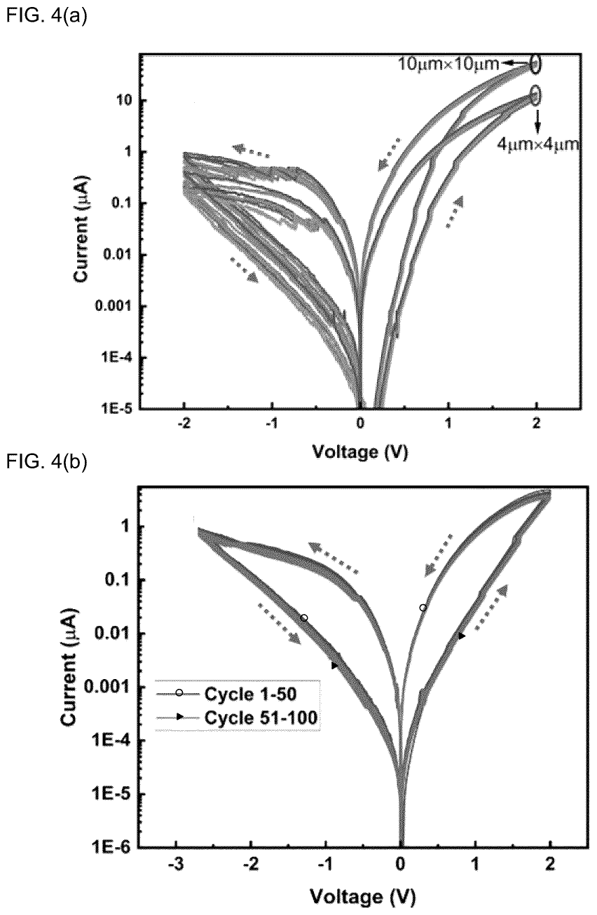

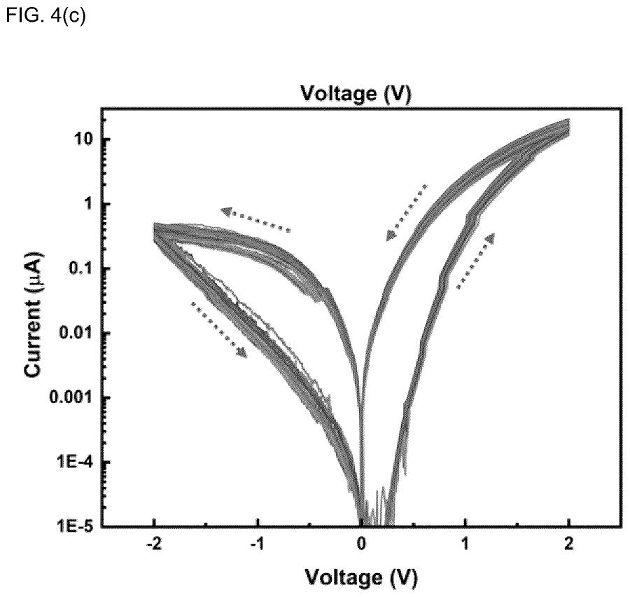

The conduction of the device scales well with the device area, which indicates a nonfilamentary type of conduction. FIG. 4(a) shows a total of twenty devices' IV characteristics with two different device sizes: 10 μm×10 μm and 4 μm×4 μm. Also, FIG. 4(c) shows 50 more 6 μm×6 μm devices' IV characteristics. As can be seen from those figures, there is little device-to-device variation as no forming or filament is needed, depicting the good uniformity of the device's volatile characteristics. As can be seen from the figure, there is little device-to-device variation as no forming or filament is needed, and conductance is proportionally larger for larger area devices. The devices can sustain repeated cycling without much degradation, as shown in FIG. 4(b), representing the robustness of the devices.

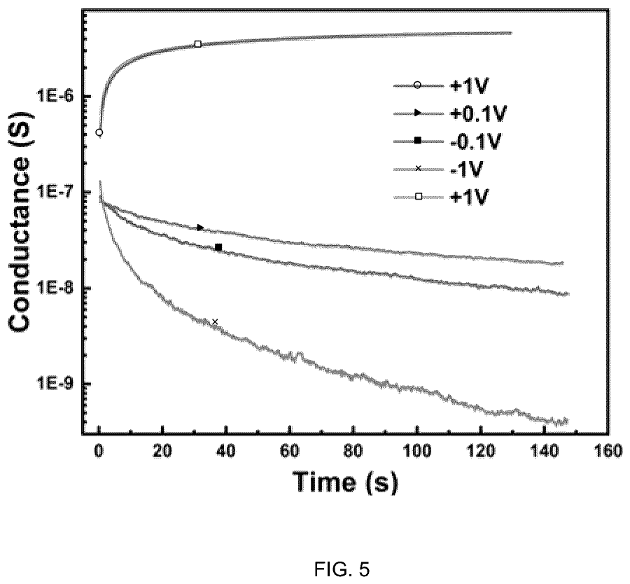

Another important phenomenon observed from the devices is their self-relaxation behavior. To understand this, several systematic tests were performed. First, a very small read voltage of −0.1V was applied to check that there was no conductance change from the fresh device. Once +1 V was applied to the device, the conductance increased (changed from HRS to LRS), indicated by the black colour curve (2^{nd} curve from top) in FIG. 5. FIG. 5 is a plot showing self-relaxation and voltage-assisted relaxation from the device (absolute value of the conductance was plotted for negative voltage).

Next, a small read voltage of −0.1V and +0.1V were applied to capture the self-relaxation towards lower conductance, which can be seen from the red colour curve (3^{rd} from top), confirming the volatility of the memory device. A higher negative bias of −1.0V shows similar but voltage-assisted relaxation to a much lower conductance state (blue colour curve 4^{th} from top). After changing the polarity back, the conductance returns to the original behavior, represented by the green colour curve (5^{th} from top), which largely accelerates the relaxation process and can be a way to speed up the system for practical applications. After changing the polarity back, the conductance returns to the original behavior, represented by the violet color curve (top curve from top). It is worth noting that due to the cathodic nature of TiOx, the center voltage of the ion insertion/extraction is not at 0V, which leads to the monotonic conductance drift between cycles depending on the voltage sweep window. As an example, when the negative voltage is not enough to fully extract the ions, the corresponding conductance drifts up appreciably from cycle to cycle (FIG. 2(a)). When sweeping asymmetrically instead (−2.7V to 2V), as shown in FIG. 4(b), the cycle-to-cycle drift becomes negligible. Therefore, the thermodynamic center of the system is approximately at −0.35 V, indicating a spontaneous redistribution of Li ions due to chemical potentials. This is also the origin of the system exhibiting faster conductance change at 1 V than at −1 V (FIG. 5).

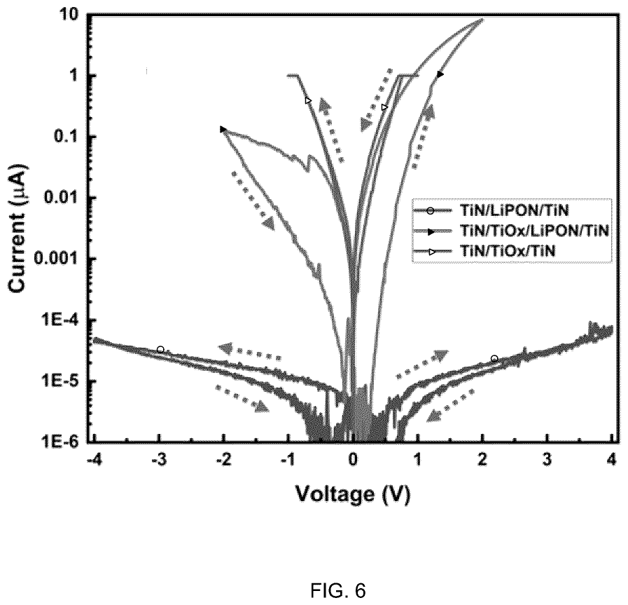

The strong volatile behavior in these devices is a combined result of the electrolyte LiPON and the cathodic TiOx. To verify this, control devices with only TiOx and only LiPON of the same 12 nm thickness were fabricated, and the characteristics are shown in FIG. 6. The LiPON-only devices are extremely resistive and exhibit different hysteresis changes (dashed arrows, curve rotation is different from the volatile changes) due to lagged charging and discharging of their capacitance with large RC constant. Whereas, the TiOx only devices before forming have small hysteretic behavior because the TiOx is populated with some oxygen vacancies that can also migrate especially under electric fields, and more so in hot spots (such as during the forming process).

The LiPON/TiOx hybrid devices have intermediate conductance as expected, and the much stronger volatile change can be attributed to their mutual influence. When LiPON was grown with reactive sputtering from the Lithium phosphate target, some Li ions were already incorporated inside the TiOx layer and created ionic defects ready for voltage manipulation. LiPON functions as a Li source and reservoir and can absorb or release ions at applied biases. TiOx functions as the cathode and its conductivity varies with the concentration of oxygen vacancies. Also, TiOx is often used as electrodes in rechargeable batteries where Li ions can travel in and out of the nanostructures, easily forming intercalated ion storage and reducing TiOx. With the ion intercalation and modified TiOx stoichiometry, the conductivity of the devices increases or decreases accordingly, analogous to the synapse systems in its stimulated conductivity modulations.

To emulate the brain-like synaptic functions, pulse-dependent characteristics from the devices are required as most of the signals in the biological brain are similar to short pulses. Synaptic plasticity, which is defined as the proficiency of neurons to adjust the level of connection strength between them, is one of the most important aspects of neuromorphic computing. In biological synapses, once an action potential is generated at the axon, it induces a Calcium ion influx into the presynaptic neuron and releases neurotransmitters. These neurotransmitters then migrate to the postsynaptic receptors temporarily modifying the synaptic efficacy. If there is another identical action potential generated before the recovery time of the calcium ions, the response from the postsynaptic neuron becomes higher compared to its first one. This effect is known as paired-pulse facilitation (PPF). Likewise, a train of consecutive identical pulses of a certain duration result in a gradual augmentation of synaptic plasticity, which is known as post-tetanic potentiation (PTP).

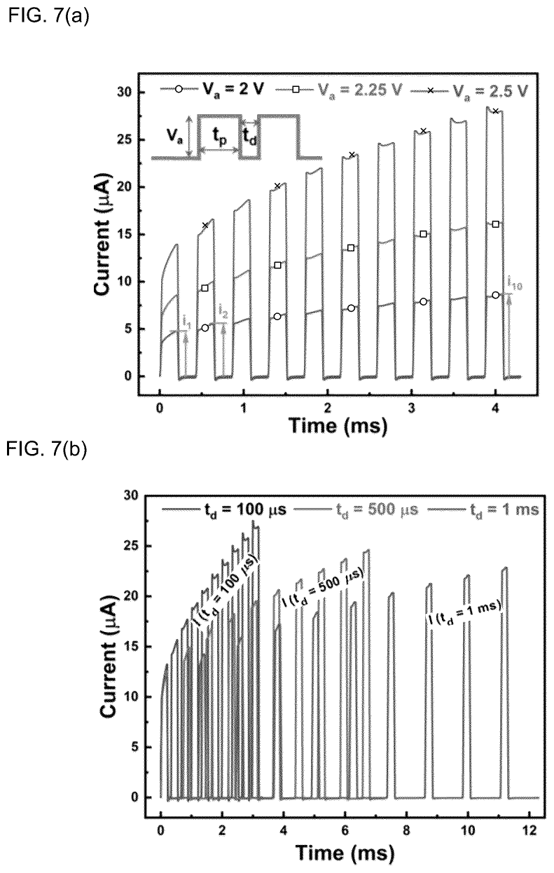

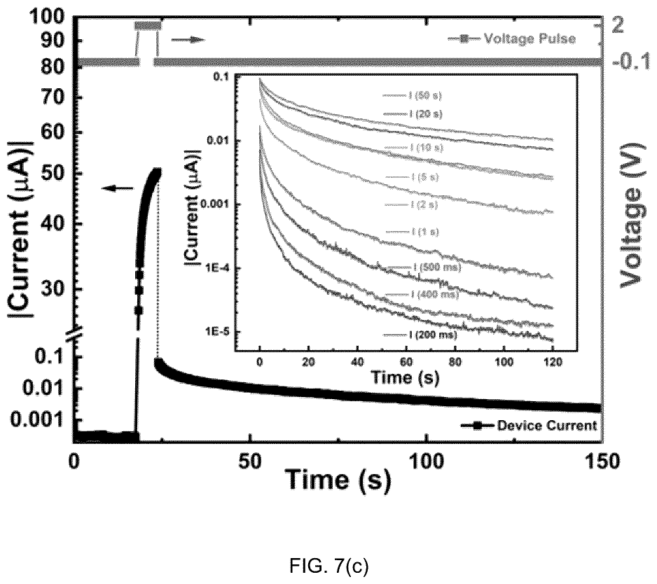

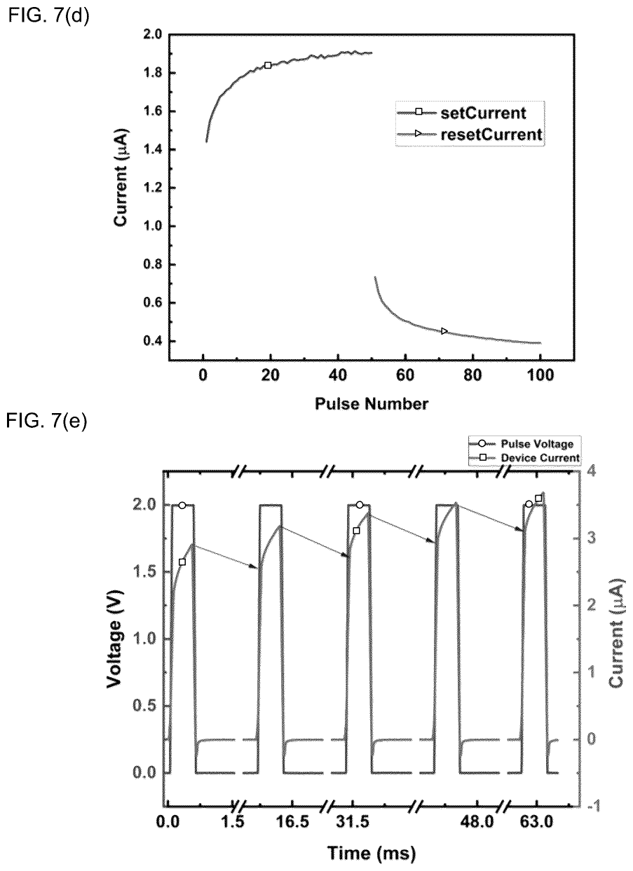

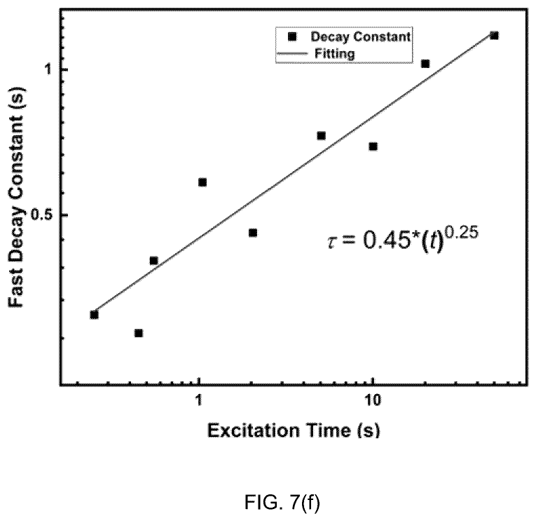

The inset of FIG. 7(a) shows the key parameters of the applied pulses on the devices, including pulse amplitude Va, pulse duration tp, and pulse delay td. The indexing of the PPF is defined as the ratio of the current value of the second pulse relative to the current value of the first pulse, whereas that of PTP is represented by the ratio of the current value of the 10th pulse to the current value of the first pulse. The pulse amplitudes are first varied to observe their effects on device conduction. As can be seen from FIG. 7(b), when the applied potentials are higher in amplitude, both the PPF and PTP increase much faster. This fact can be explained by the number of ions participating inside the device is higher when the electric field is higher, resulting in a much higher conductance increase. The potentiation and depression characteristics are shown in FIG. 7(d). The first fifty pulses are positive and result in potentiation from the device and the next fifty pulses are negative and result in depression characteristics.

Synaptic plasticity is a function of the spike rate as well. Spike rate modifies the number of neurotransmitters from the presynaptic neuron, which modifies the strength of synapses; this process is known as spike-rate dependent plasticity (SRDP). Analogous to biological synapses, the conduction also depends on the delay between pulses as the competing self-relaxation behavior exists. When the pulse interval is of high value, some ions relax back and the conductance increase is slower, which is shown in FIG. 7(e). This is why a longer delay results in a smaller final current despite the accumulated pulse time remaining the same, which is depicted in FIG. 7(e). Thus, Li-ion imbued TiOx shows the SRDP of a biological brain and can be used for artificial synaptic devices.

A continuous biasing approach was performed to determine the timescale of the volatile memory device. To capture the decay after excitation, a continuous bias of different time intervals and amplitudes was used (for example, 2 V for 5 seconds was used to capture the potentiation; and to capture the decay, a small negative voltage, −0.1 V, was used). FIG. 7(c) shows the overall voltage pulse and corresponding current. Also, the inset of FIG. 7(c) shows that a larger duration of voltage stress results in slower conductance decay, which can be attributed to a large number of Lithium-ion migrations. Next, the current decay (durations of 1 s to capture only the relevant, fast relaxation) was fitted with an exponential decay and the extracted time scales. The fitted results, shown in FIG. 7(f), can be approximated with a power-law relationship, meaning the short-term memory can be tuned with the excitation duration, which was used for voice recognition applications as described in the following sections. Thus, the device of the present embodiments shows a unique feature: tunable volatile memory.

It is noted that the dual volatile and non-volatile device has temperature dependent characteristics.

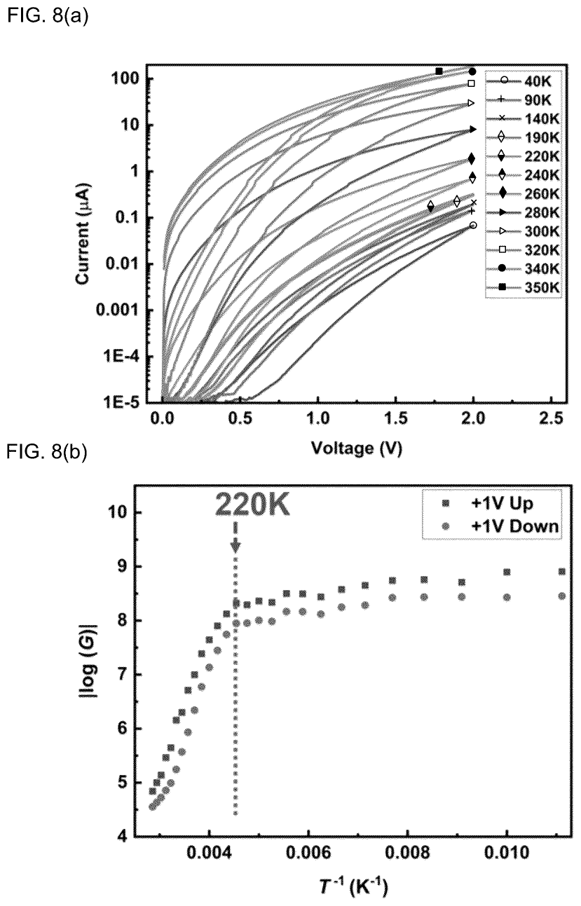

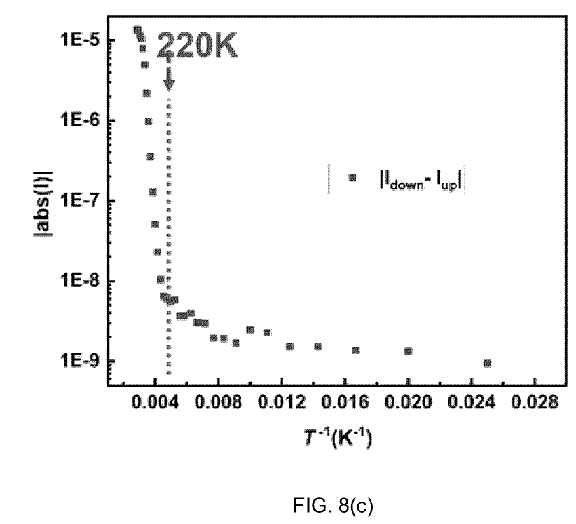

The participation of ions can be distinctly identified by varying the device temperature as ions tend to freeze out easily at reduced temperatures. In testing, the temperature was varied over a wide range, from 40K to 350K, while the voltage sweep was fixed from 0V to 2V (Up Sweep) and then 2V to 0V (Down Sweep). FIG. 8(a) shows that before the temperature reached a certain threshold value, the IV loop openings were small and device behavior did not change much, but changes were more pronounced above the threshold temperature, meaning some thermally activated conduction channels are now participating.

To determine the threshold value, the discrete current data value at +1V is extracted at both up sweep and down sweep and plot it as a function of the inverse of Temperature, i.e. 1/T. There is a clear slope change at 220K as shown in FIG. 8(b). This transition can be attributed to lithium ions becoming frozen below this threshold temperature, which is close to the reported freezing temperature of Li ions. Therefore, only thermally promoted Li ions are able to migrate. On the other hand, the relative change under sweeping voltage is a result of the applied electric fields driving the already promoted ions, therefore not as temperature dependent. This effect can be further illustrated in FIG. 8(c), where the current difference between the up and down sweep as a function of temperature is plotted.

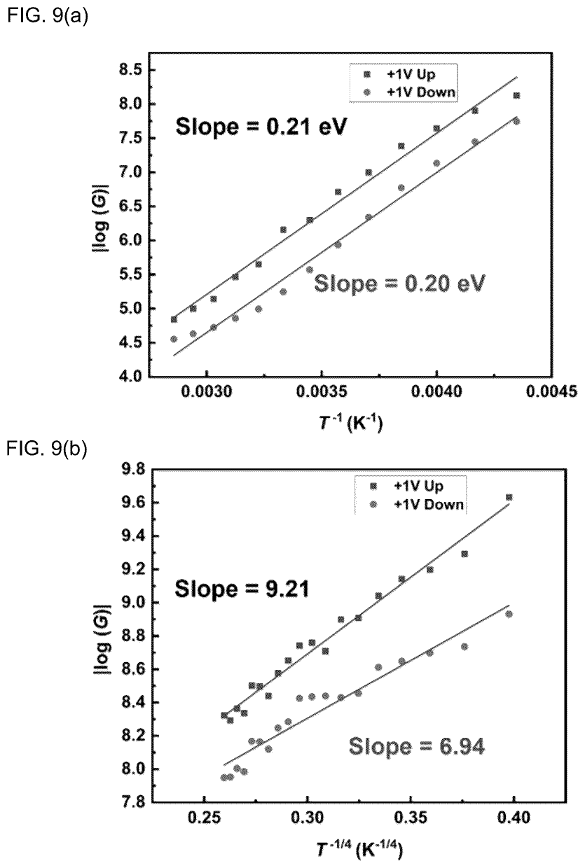

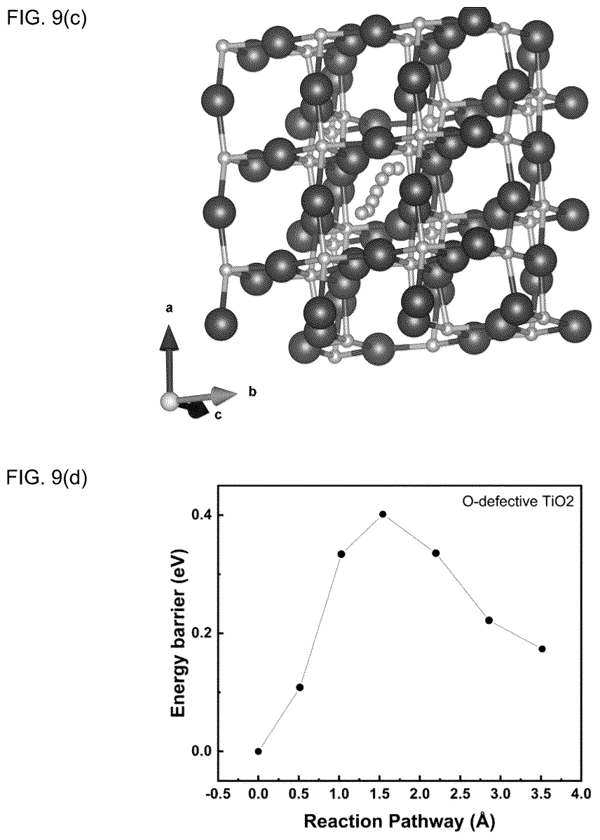

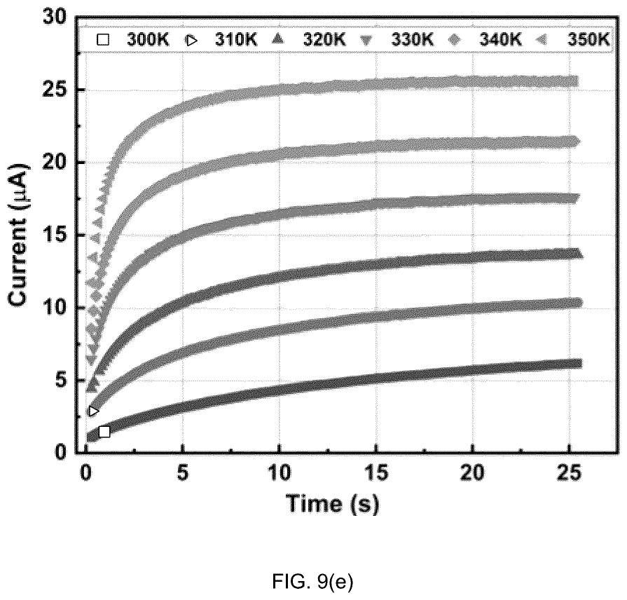

The slope of the semilog plot with respect to 1/kT, which is known as the activation energy barrier, was calculated from FIGS. 9(a) and 9(b) above and below the transition temperature, respectively. Above the transition temperature, the activation barrier was found to be around 0.20 eV, which approximately corresponds to the DFT calculated value, a low energy barrier of around 0.4 eV as shown in FIGS. 9(c) and 9(d), for Li-ion migrating through the O-defective structure of anatase TiO₂, compared to the 0.588 eV, 0.608 eV and 0.632 eV reported elsewhere for pristine anatase TiO₂ structures.38 Below the transition temperature, the Li ions are frozen and the conduction mechanism is mostly dominated by variable-range hopping (VRH), which is much less temperature-dependent and a linear relation between conductance and the Temperature (T−¼) was found. This conduction mechanism is similar to reported mott VRH at low temperatures.

The constant voltage stress curves above the threshold temperature are shown in FIG. 9(e). The applied voltage was +1V. It is clear that higher temperature leads to higher final conductance and faster conductance change. Faster ionic motion is expected for higher temperatures; therefore, the system can reach dynamic equilibrium significantly faster. The temperature is a useful controlling parameter for the system if tuning operation speed is necessary.

The non-volatile characteristics of the dual volatile and non-volatile device of the present embodiment is now described.

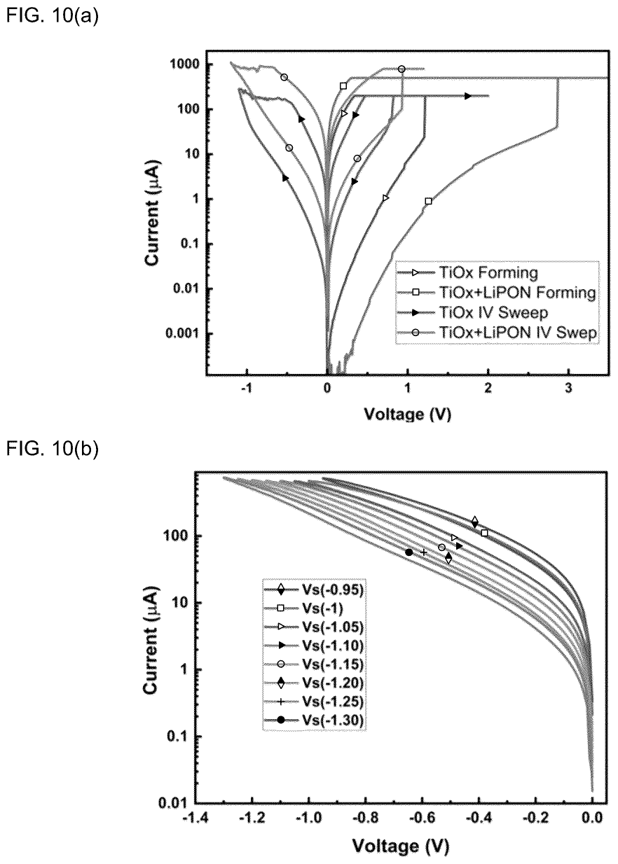

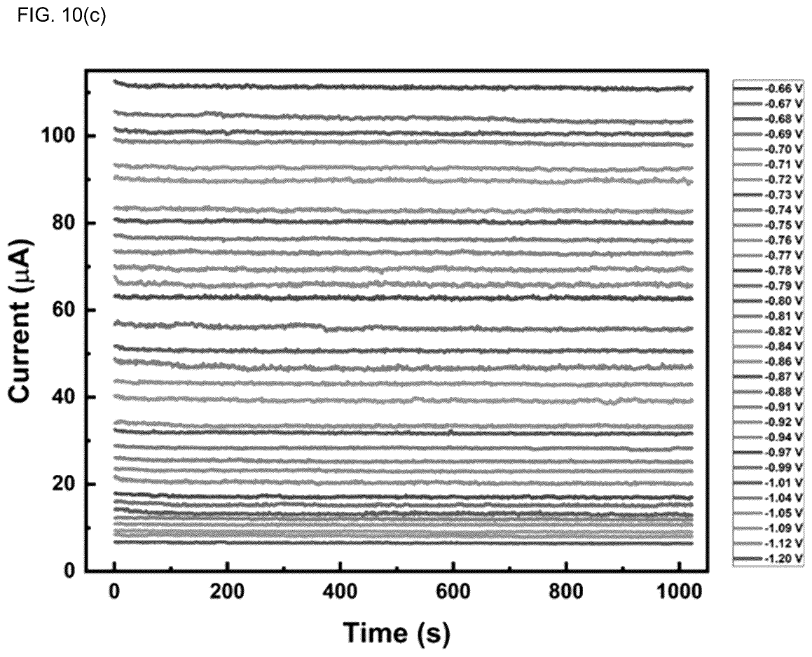

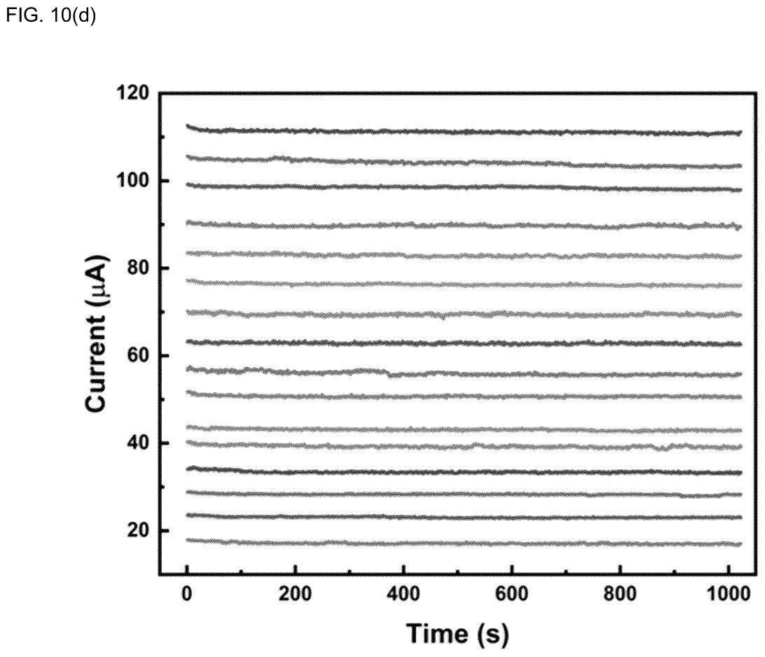

The same volatile memory device can be configured into a non-volatile one by an electroforming process. The forming process forms conductive filaments in Li-imbued TiOx resistive switching devices, and the device is SET to LRS. The device can be RESET to HRS by applying opposite polarity voltages, which has the effect of severing or breaking down the previously formed filaments. A comparison of the electroforming behavior of hybrid 8 nm TiOx/4 nm LiPON devices with pure 8 nm TiOx control devices is shown in FIG. 10(a), and the former need higher forming voltage and larger compliance current to form appropriate conductive filament width. This is reasonable as LiPON is a good electrical insulator and a large fraction of the overall applied voltage is dropped across this layer instead of TiOx.

After fabricating the devices, the RESET and SET operations are performed for both devices. For the reset operation, the voltage is kept at a fixed value rather than a compliance current as current may vary from device to device. A compliance current has a preset upper limit designed for a particular device to avoid permanent breakdown of its switching layers, which would result in permanent breakdown (shorted). The compliance current is used in the transition from HRS to LRS (a SET operation), and ensures the desired reversible soft breakdown is maintained. As clearly shown in FIG. 10(a), the Li infused TiOx becomes non-volatile after filament formation. Overall, these devices have higher conductance despite the total layer thickness being higher, because TiOx becomes more defective in the presence of Li ions, and LiPON likely experiences dielectric breakdown and no longer participates.

This device of the present embodiment can be reset to multiple resistance states without overlapping in between, meaning it is capable of storing multibit information. When stopped at different reset voltages, the current from the device is gradually reduced, as shown in FIG. 10(b). A retention test is then performed, immediately after each reset, shown in FIG. 10(c). With an increment of 0.01V, 32 states can be set with a margin of approximate 0.5 μA. The devices retain more than 32 states for thousands of seconds without much noticeable change. This ensures sufficient margins for programming 4-bit (16state) information on each device as shown in FIG. 10(d), which will be assumed in the next session for the proposed circuit integration.

It is worth pointing out that the Li-containing devices' transition from volatile to non-volatile is irreversible, and once the conductive filament is formed, the system behaves very similarly to pure TiOx devices with non-volatile memristor behavior.

The dual volatile and non-volatile device of the present embodiment is now described in the application of memristor-based reservoir computing.

Reservoir computing (RC) is a computation framework that maps input signals to higher dimensional space, through a non-linear mapping “reservoir”. “Reservoir” can be a dynamic system that evolves in time, which can be expressed as f(t+1)=f(t, input). The volatile switching behavior of the fabricated device of the present embodiment shares similar characteristics with a dynamic reservoir: the future resistance state (f(t+1)) is dependent on the applied voltage (input) and current resistance state (f(t)). To illustrate the neuromorphic capabilities of the device of the present embodiment, the devices were applied to a physical reservoir computing system for voice recognition tasks.

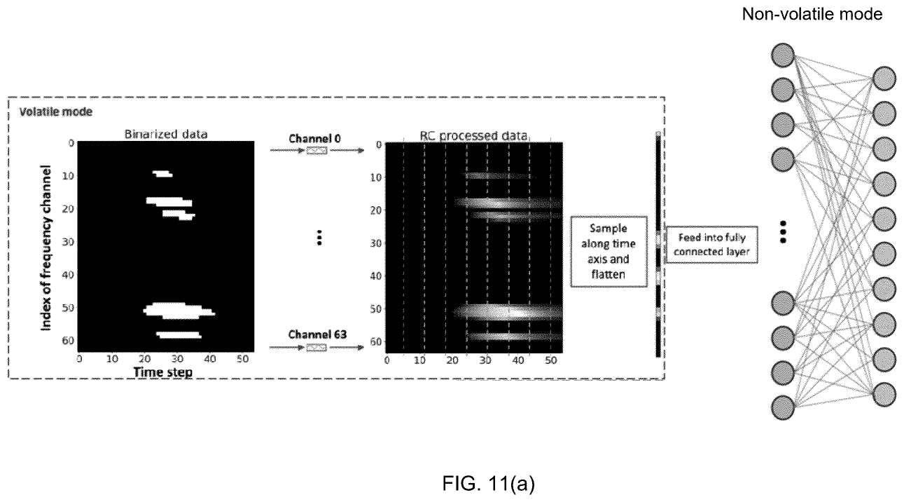

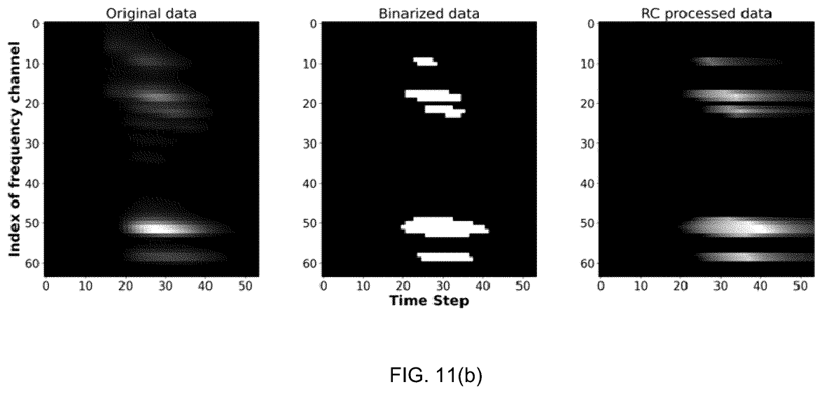

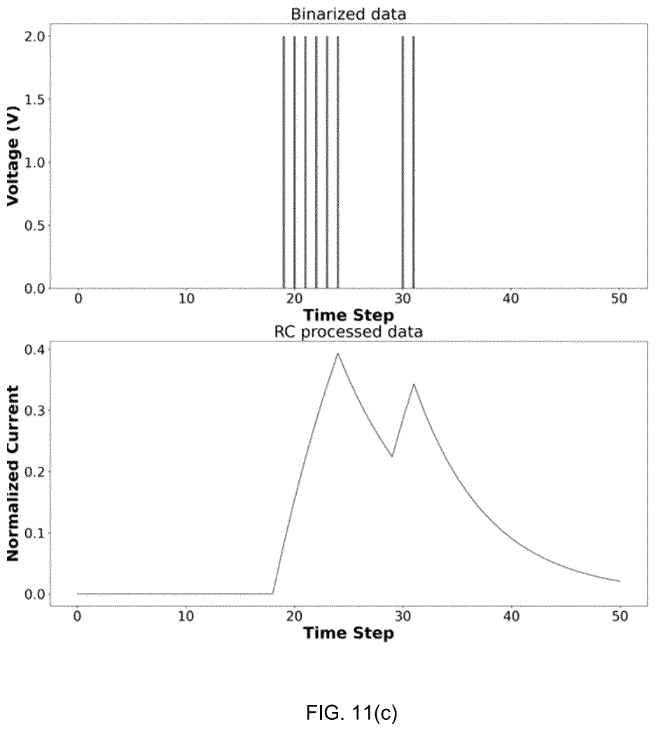

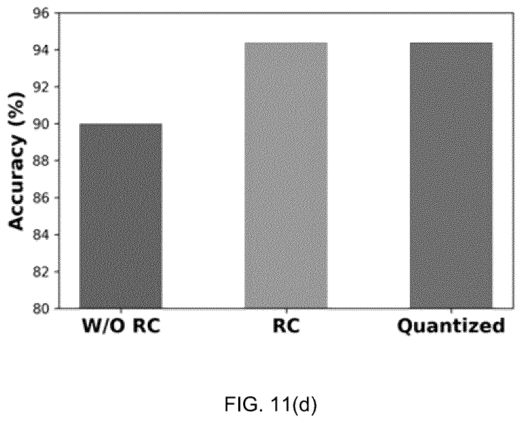

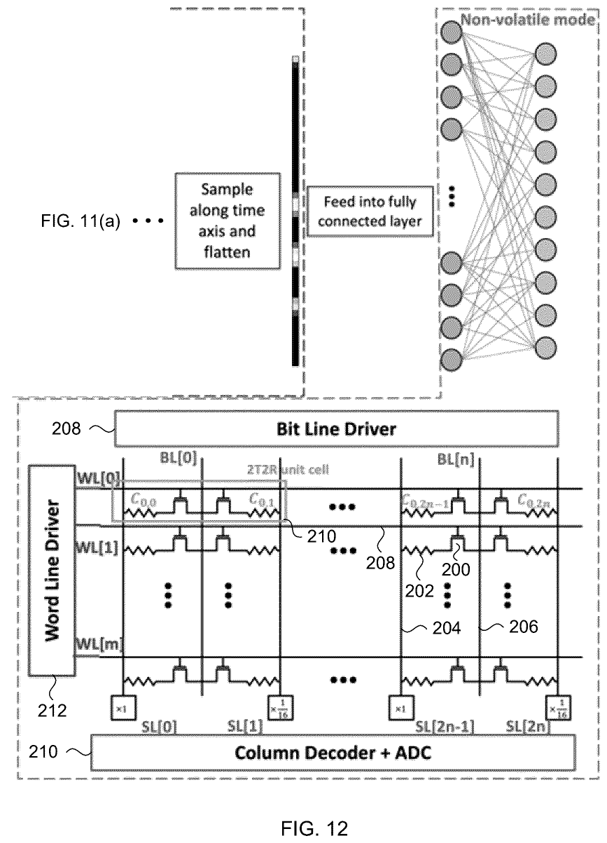

The work flow of the RC system is illustrated in FIG. 11(a). After pre-processing raw voice data using Lyon's passive ear model, the generated cochleagram (frequency channel vs time) is normalized and binarized (with a threshold value of 0.2). The Cochleogram of original voice data and binarized one with a threshold value is shown in FIG. 11(b)). The data vector of each frequency channel (along time step axis) is converted into a voltage input vector (with data “0” representing 0V and data “1” representing 2V), and the time step of the voltage input vector is 33 ms. The voltage input vector of each channel is fed into the volatile device connected with the channel. As shown in FIG. 11(c), the conductance of the volatile device will change (potentiate or self-relax) based on the voltage input vector. The RC processed data from binarized input data almost perfectly resembles the original voice data. Next, the conductance value of each device is evenly sampled along the time axis (8 data points sampled in our simulation). Sampled conductance values of 64 channels are flattened into a 1D feature vector and fed into the fully connected layer to generate the classification results.

The whole system has been trained for 300 epochs, the classification accuracy of the RC model, defined as the average accuracy of the ten-fold cross-validation, is 94.4%, which outperforms the binary data without RC processing using the same network architecture by 4%, as shown in FIG. 11(d). The accuracy improvement is achieved without computation overhead. A performance comparison between existing literature and the demonstrated device of the present embodiments is shown in Table 1 below.

Table 1 below is a performance parameter comparison between the existing literature and the device structure of the present embodiments.

TABLE 1

| | | Volatile | Non- | | |
|---|---|---|---|---|---|
| | Vola- | Time | vola- | Multi-bit | |
| Device | tility | Tunability | tility | Capability | Accuracy |
| Pd/SiO₂:Ag/Pt | Yes | No | No | No | 83% |
| Pd/Au/WOₓ/W | Yes | No | No | No | 99.2% |
| Ti/(TiOₓ/TaO_{y})/Pt | Yes | No | No | No | 99.6% |
| Pt/SiO₂:Ag/Pt | Yes | Yes | No | No | 99.6% |
| TiN/TiOx/LiPON/TiN | Yes | Yes | Yes | Yes | 94.4% |

*Li, Ruiyi, Haozhang Yang, Yizhou Zhang, Nan Tang, Ruiqi Chen, Zheng Zhou, Lifeng Liu, Jinfeng Kang, and Peng Huang. “Adjustable short-term memory of SiO x: Ag-based memristor for reservoir computing.” Nanotechnology 34, no. 50 (2023): 505207.

According to advantages of the present embodiments, the platform excels with great device tunability and platform customizability.

The fully connected layer discussed above is based on software simulation, each weight inside the layer is stored in the format of a 32-bit floating point number (float32). Arithmetic operations as well as storage of floating-point numbers are resource-intensive and not energy efficient for hardware implementation. To explore the possibilities of scaling down the representing bits of weights, post-training quantization (PTQ) is used to map the trained weights from float32 to int8. The quantized model is validated using the same validation dataset, and the results show that there is no accuracy drop after quantization. Based on that, a 2T2R compute-in-memory (CIM) array is proposed (shown in FIG. 12) to accelerate the operation of vector-matrix multiplication, which is used inside the fully connected layer, with the devices of the present embodiments operating in non-volatile mode.

FIG. 12 is a schematic of a CIM array according to a present embodiment. In FIG. 12, a portion of FIG. 11a is reproduced to provide context. The CIM array includes an arrangement of the dual volatile and non-volatile device of the present embodiments, where each device is represented by a transistor 200 in series with a resistor 202 between a source line 204 and a bitline 206. Only one transistor, resistor, source line, bitline and word line are annotated with reference numbers. The controlling gate terminal of the transistor 200 is connected to a word line 208. In the present embodiment, each pair of devices connected to the same bitline 206 and wordline 208 forms a 2T2R unit cell 210.

With each device programmed to store 4-bit data, the 2T2R unit cell consists of two non-volatile devices and two access transistors. Two non-volatile devices inside the 2T2R unit cell are used to store one 8-bit weight, the left device is used to represent the most significant 4 bits (MSB) and the right is used to represent the least significant 4 bits (LSB). Both devices of the unit cell are activated at the same time by the word line driver 212 which applies the necessary voltage on the selected word line 208. Both devices share the same bit line 206 signal (V_{BLn}), where a current is provided by bit line driver 208, therefore, current flowing through the MSB source line 204 (I_{SL2n-1}) would be,

$${I}_{{SL}_{2 n - 1}} = {\sum }_{m = 0}^{M} {V}_{{BL}_{2 n}} * {C}_{2 n - 1 , m} ,$$

while the current for Lots line (I_{SL2n}) is

$${I}_{{SL}_{2 n}} = {\sum }_{m = 0}^{M} {V}_{{BL}_{n}} * {C}_{2 n , m} .$$

I_{LSB} is fed through a 1/16 current mirror so that the sum of I_{MSB} and I_{LSB} can be used to represent a 8-bit value. The current sum, (I_{MSB}+ 1/16*I_{LSB}), is sampled by ADC, which would be digitalized and output the 8-bit product results. The column decoder 210, which includes the ADC, selects the source lines to access.

The configuration of the voice recognition system is now described. Voice data was converted into a cochleagram (frequency channel vs time) using Lyon's passive ear model. After conversion, the processed data consists of 64 channels, each of which would be the input vector applied to the reservoir. To reduce the training data budget, input vectors are binarized first with a threshold value. Each data point of the binarized input vector would be the voltage applied to the physical reservoir, with “1” representing 2V and “0” representing 0 V (See FIG. 11(c)). After RC processing, the data size is shrunk again by evenly sampling eight data points on the time scale and fed into a fully connected layer for classification. The fully connected layer is pre-trained and optimized using the RMSprop method, and softmax is used to convert the output of the fully connected layer to the classification result. A 10-fold cross-validation is used to train (450 samples) and validate (50 samples) the RC system.

In this example, the wordline voltage is 3.3V while the bit line voltage is 0.2V, based on 180 nm circuits.

The above described 2T2R embodiment can be configured as a 1T1R cell that provides a 4-bit value. Alternately, with higher quality fabrication the single 1T1R cell can be programmed to store 8-bits of information.

In a present embodiment, the volatile devices form an array as the training layer, and the non-volatile devices are connected right to them as the training weight storage layer. However, the devices do not necessarily need to be formed in an array configuration.

In yet another embodiment, the dual volatile and non-volatile devices can be configured as part of a Field Programmable Gate Array unit (FPGA) with all the devices operating in the volatile mode. Depending on the application, the end user can program the devices into different neuromorphic layouts by selectively setting devices into the non-volatile mode.

In a further embodiment, the devices can be engineered with ion diffusion barriers (sitting between the ion reservoir and ion active layers): ions can still be effectively injected via electric fields, but their relaxation back can be made as slow as one needs, such as hours, days, or weeks. Such diffusion barriers can be configured based on Boltzmann statistics, ie. exp(−Eb/kT), where Eb is the barrier height, k is Boltzmann constant, and T is temperature in K. Alternatively, one can physically narrow down the ion migration path by creating constrictions in the barriers (such as a pinhole) or adding ion conductive channels (such as a 2D material or a 1D nanowire) to slow down the process controllably. This application is suited for security applications such as secret key distribution, where the devices retain sensitive information with a predefined time, and then effectively self-erases the data, without needing any external trigger.

In summary, one of the embodiments presents a demonstrated Li-ion imbued TiOx memory device, with both volatile and non-volatile memory capabilities. Before forming, the devices show inherently uniform gradual conductance change upon the application of external bias due to the controlled ionic motion. A self-relaxation phenomenon confirms the volatile nature of the memory. The Li-ion-induced vacancy creation inside TiOx resembles Calcium-ion-induced synaptic modulation inside biological synapses. Pulse-dependent results strongly resemble the different brain functionalities such as PPF, PTP, and SRDP characteristics. The timescale of the volatile memory devices can be tuned by changing the voltage pulse widths. In addition, the same volatile device can be transformed into non-volatile memory by an electro-forming process. To illustrate their performance, both volatile and non-volatile versions of the devices were applied to a proposed reservoir computing architecture and performed voice recognition tasks with over 94% accuracy. This demonstrated general platform is configurable to mimic brain functions on a hardware level.

The TiOx/LiPON combination is an example of one particular embodiment. The above-described principles work for many other memristive devices. For example, other metal/metalloid compounds coupled with the controllable embedment/extraction of ions (mostly cations like hydrogen/alkaline/alkaline-earth/transition-metal ions and anions like halogen/chalcogen/pnictogen ions) will more or less show similar volatile behavior. Memristive materials likely should also show the non-volatile behavior after a forming process.

As previously mentioned, programming multiple logic states in non-volatile memory, including for the aforementioned resistive device operating in the non-volatile mode, can be time intensive due to the requirement to verify the programming, or writing of the intended state.

In the standard write-verify schemes, the pulse amplitude (voltage or current) is tuned with nondeterministic feedback, this leads to multiple cycles of erasing and verifying and slows down the overall process.

According to another embodiment, a novel write-verify algorithm for multi-level programming of RRAM (Resistive Random Access Memory) is discussed. The algorithm of the present embodiment utilizes a feedback mechanism to predict and tune parameters (due to observed logarithmic time dependence) for multi-level programming. This is in sharp contrast to the prevailing technologies that use pulse amplitudes and trial-and-error to perform the tuning.

The novel write-verify algorithm of the present embodiment aims to speed up multi-level programming of RRAM based on specific characteristics of RRAM devices. RRAM devices can be programmed to store information in the form of resistance values. For 1-bit storage, high resistance state (HRS) can be used to represent “0” while low resistance state (LRS) can be used to represent “1”. Writing of the 1-bit RRAM devices includes SET (HRS to LRS) and RESET (LRS to HRS), which apply voltage pulses to RRAM devices to switch the resistance state. It is noticed that SET or RESET can be partially applied to RRAM devices by tuning the voltage amplitude or pulse duration, the resistance value of RRAM after partial writing would fall between HRS and LRS and such intermediate resistance states are found be stable over the time, which makes it possible to achieve multi-level programming of RRAM devices.

The write-verify algorithm makes use of the controllable variation in the RRAM RESET process (logarithm time dependence) to predict write parameters and write the desired resistance states. This allows the process to be much faster than the common trial-and-error types of writing schemes. It is noted that the SET process is stochastic and cannot be controllably operated so the algorithm focuses on structuring the RESET process.

More specifically, for a given fixed voltage, the transient current analysis during RESET shows a universal logarithmic time dependence on fabricated TiN/TiOx/TiN RRAM devices. Current induced rupture of the conductive filament makes it possible to time the writing of certain resistance states. In contrast, the voltage driven SET shows stochastic behavior over write time.

Described herein is a state aware multibit write algorithm based on the logarithmic time dependence of RESET, which is used to deterministically estimate write time needed between states writing. Compared to the conventional write-verify algorithm, the state-aware write verify (SAW) algorithm of the present embodiment reduces total write time by 75% compared to conventional write verify algorithms, such as two-step verify and self-termination write, and achieves a minimum conductance gap of 5 μS without overlap between states.

More specifically, according to the present embodiments, the observed logarithm time dependence provides a feedback mechanism to tune the time duration of write pulse during multi-level programming. The time duration is dependent on the read current difference between current resistance state and target resistance state, therefore, the desired time duration of write pulse for specific target resistance states can be deterministically calculated (read current difference is measured with verify operation). This would eliminate the number of intermediate-verify steps needed.

As will be discussed later for the present embodiments, two status flags (Oscillation and Monotone) are used to monitor the status of writing, which prevents the system from entering slow or dead loops. Oscillation is defined as the resistance state after writing oscillates around target value without converging, amplitude of write pulses would be decreased if the oscillation flag is triggered. Monotone is defined as when the read current consistently stays above or below the target value, amplitude of write pulses would be increased to speed up the writing process. These two status flags help to eliminate the influence of noise and variation during writing.

Experiments validating the presently described state-aware write verify (SAW) algorithm were executed on a fabricated memristor device.

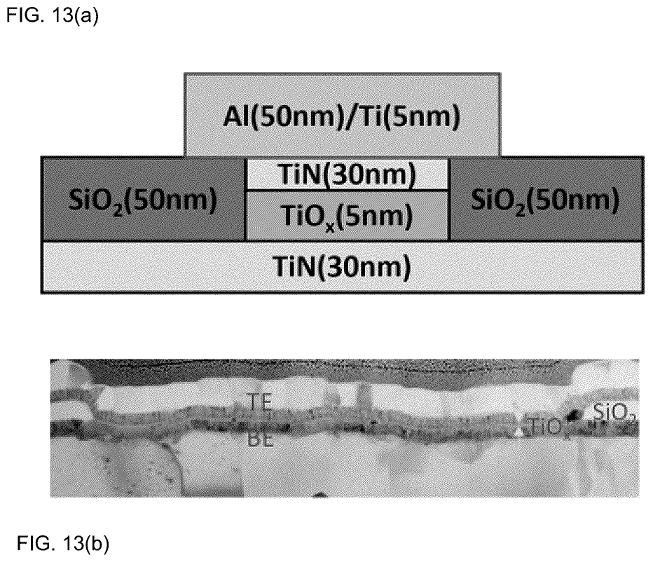

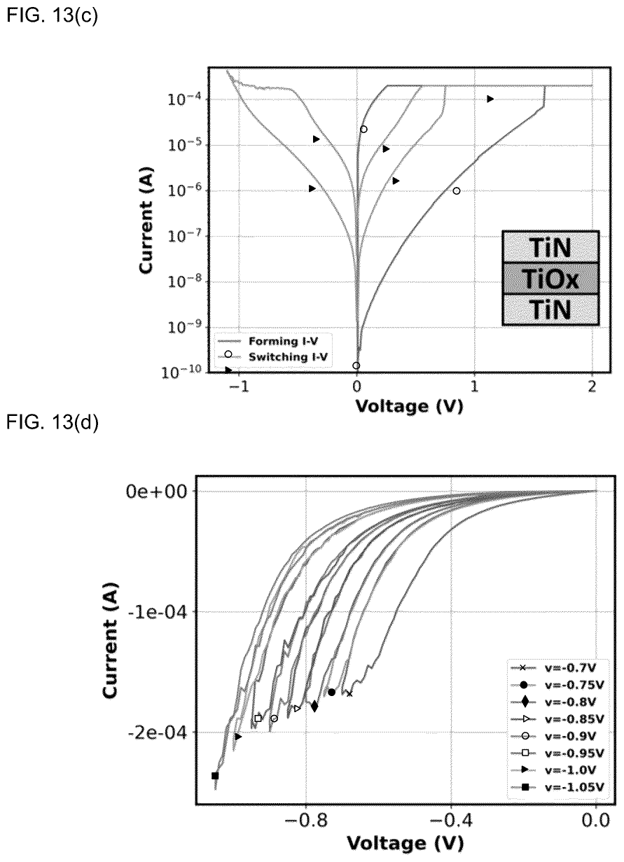

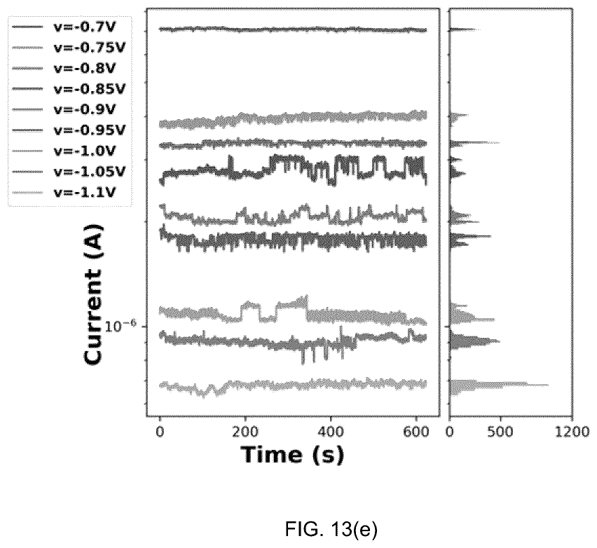

The schematic of the fabricated TiN/TiOx/TiN devices according to another embodiment is shown in FIG. 13(a). The bottom TiN electrode is grown on the SiO₂/Si substrate using DC reactive magnetron sputtering, followed by lithography and ion-milling to define the electrode shape. Active device regions with a minimum area of 4 μm×4 μm are fabricated on top of the TiN electrode with PECVD-grown SiO₂ as the isolation layer. The full stack of TiOx/TiN and Ti/Al (top electrode) is then deposited on the pre-fabricated bottom electrode and patterned with a lift-off step. The cross section STEM image of a typical device is shown in FIG. 13(b) with the thickness of active TiOx layer being 5 nm. Electrical characterization is conducted using the Keithley 4200A parameter analyzer equipped with pulse measurement units, based on which custom control codes are written to achieve the desired functionality of our proposed SAW algorithm.

In the present example, the fabricated RRAM devices are electrically formed by applying a positive voltage (˜1.5 V) on the top electrode, and a compliance current is applied to prevent hard breakdown during the FORMING. The I-V characteristic after forming (FIG. 13(c)) shows bipolar resistive switching behavior with SET under positive bias (˜0.5 V) and RESET under negative bias (˜−1.2 v)). By varying the stop voltage of RESET in DC sweeping, it is observed from FIG. 13(d, e) that the fabricated RRAM devices are multi-level capable with clear margins between neighboring resistance states. However, it should be noted that multi-bit writing using DC sweeping takes a few seconds to finish one writing on each device, which while possible is not practical for programming larger RRAM arrays. Literature results indicate that there exists a voltage-time dependence in writing high resistance state (HRS), where larger RESET bias takes shorter write time for the single bit storage. To explore the multi-level encoding capability of fabricated RRAM devices without compromising write speed, transient analysis of RESET transition is required to obtain an understanding of such processes.

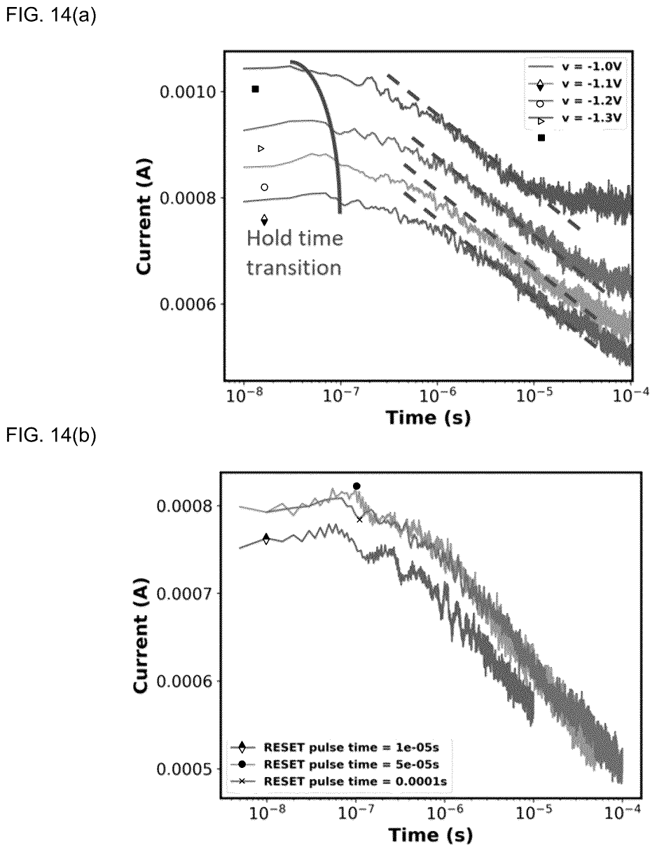

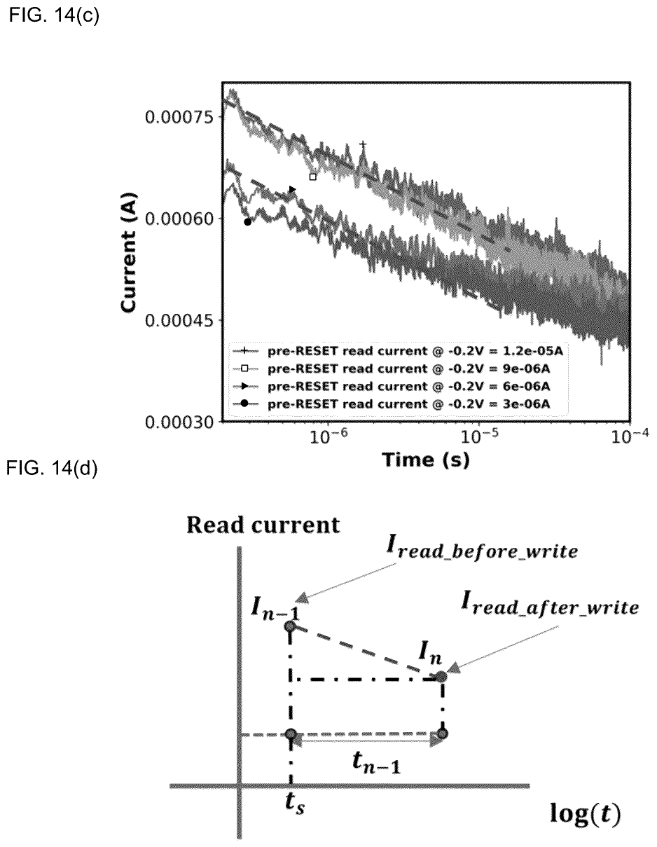

Transient current analysis of RESET is conducted by applying constant voltage pulses with various bias amplitudes to devices in low resistance state (LRS) and sampling the current change during the transition towards HRS (5 ns sampling period). The time evolution under different voltage biases is shown in FIG. 14(a), which shows a clear logarithmic time dependence. The slope of the transition from LRS to HRS is independent of the applied voltage. However, under larger bias voltages, it takes shorter time for the switching current to saturate, which is consistent with the reported voltage time relationship. The logarithmic behavior is an indication that a critical current density is governing the rupture of the conductive filament, while the hold time is a sign of ramping up to a critical temperature beforehand.

The hold time (time needed to trigger RESET transition), however, decreases from 100 ns to 20 ns when increasing the bias voltage from 1.0 V to 1.3 V. This indicates that localized high temperature (joint effect of current, voltage and time) is needed for the rupture of conducting filaments, and faster writing can be achieved with higher voltage. For the same bias voltage (FIG. 14(b)), RESET pulses with varied durations are applied and the transient currents show similar slopes despite the final resistance states. A similar trend is also observed for RESET transition under different initial resistance states (FIG. 14(c)).

From these results, a state-aware RESET write time calculation is developed, according to a present embodiment. This write time calculation is illustrated in FIG. 14(d). The Current-time relationship can be expressed as: ΔI=k·log(t)+b

and the slope k can be calculated from the last RESET operation:

$$k = \frac{{I}_{n} - {I}_{n - 1}}{log ( {t}_{n - 1} + {t}_{s} ) - log ( {t}_{s} )}$$

where ts is the hold time, tₙ₋₁ is the write time of the last RESET operation, Iₙ₋₁ and Iₙ are before and after read current of the last RESET operation. Estimated write time to reach the target value can be calculated as:

$${t}_{n} = ( {e}^{\frac{{I}_{n} - {I}_{target}}{k}} - 1 ) \cdot {t}_{s}$$

where I_{target} is the target value of the read current, which can be set to any predetermined level for the application.

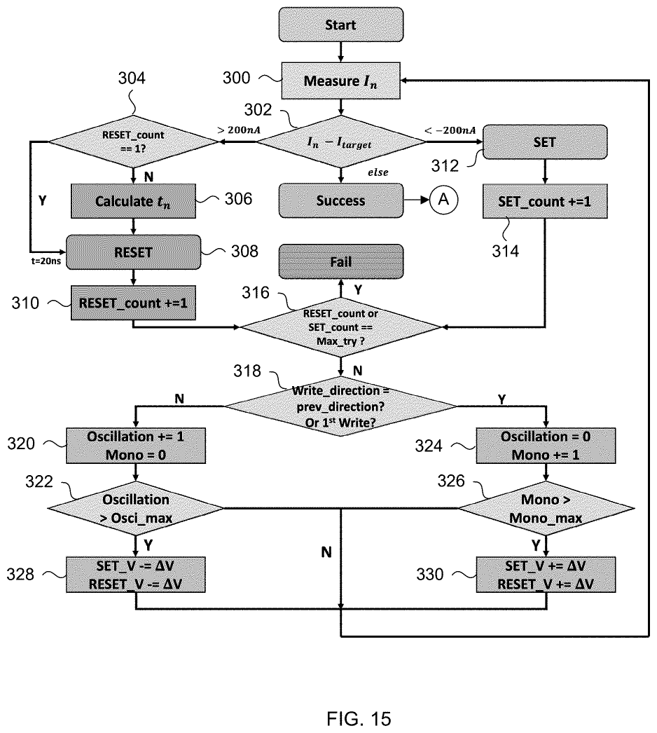

The flowchart of the SAW algorithm based on this proposed RESET write time calculation is shown in FIG. 15. Starting at step 300, the resistance state of devices is measured using a −0.2 V read pulse with the sampling time being 1 μs.

These are example voltages and times, where it should be understood that different voltages and times can be used depending on the type of device that is being used. Read current Iₙ is compared to the target value at step 302 to determine the write direction (SET or RESET) by taking the read current Iₙ and subtracting the target value. If the difference is greater than 200 nA, for example, then the method proceeds to step 304. The method determines at step 304 if the RESET is the first RESET applied to the devices, and if yes the RESET pulse time is set as 20 ns, and the slope k is calculated based on the 1st RESET and the moving average of k is used in the following RESET time calculation. In the circumstances where the reset count is greater than 1, tn is calculated as shown earlier at step 306. Due to the limitations of the parameter analyzer, the minimum write time of RESET is capped at 20 ns, though the calculated values can be shorter when the state of the device is close to the target state. The RESET write operation is executed at 308 and a RESET counter is incremented at 310. The write time of SET is fixed at 1 μs.

Returning to step 302, if the difference between the read current Iₙ and the target value is less than 200 nA, then the method proceeds to step 312 where the SET write operation is executed and a SET counter is incremented at 314. Both steps 310 and 314 proceed to the determination step 316 to check if either the RESET count or the SET count has reached their respective maximum value. If yes, then the algorithm ends as the programming is deemed to be unsuccessful. In this situation the system can restart the entire writing sequence. Otherwise, the method advances to the next phase of the algorithm beginning at step 318. The previously described steps of the algorithm form the programming phase of the algorithm.

In the following steps write direction is compared to last write direction to update state flags and update SET/RESET bias amplitude when thresholds are triggered. This is referred to as the programming voltage correction phase.

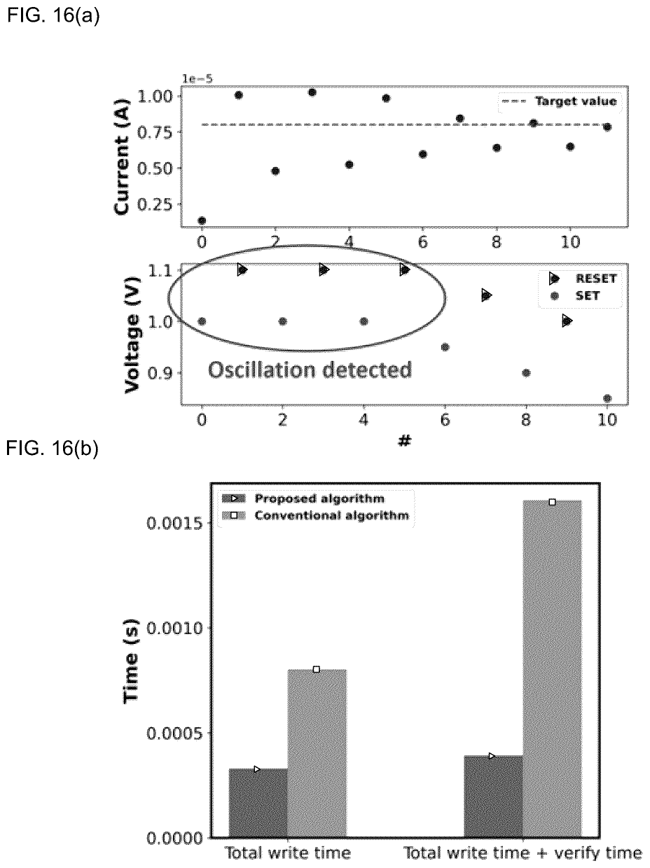

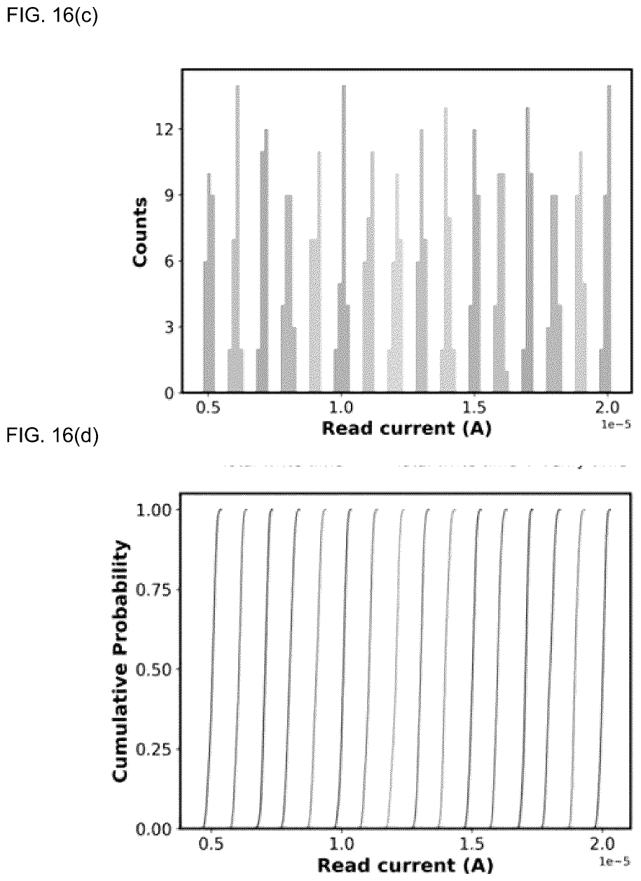

After the write pulse is applied (steps 308 or 312), a determination is made at 318 to check if the current write direction is the same or different from the previous write direction. Based on this determination one of two status monitoring flags (oscillation and monotone) are updated based on the write direction. For example, if the current write direction is RESET and the previous write direction was SET, or vice versa, then the oscillation counter is incremented at 320. Oscillation is defined as when the read current oscillates around target current with SET/RESET pairs applied to the devices (FIG. 16(a)), indicating that the bias amplitude of either SET or RESET is too large to fine-tune the resistance state. This is determined at step 322 by comparing the oscillation counter to the maximum value. On the other hand, if the current write direction is the same as the previous write direction, then the monotone counter is incremented at 324. Monotone is defined as when the read current consistently stays above or below the target value, which indicates that the bias amplitude of applied SET (or RESET) pulse is insufficient to trigger the resistance change. This is determined at 326 by comparing the monotone counter to its maximum value. It should be noted that in only the first iteration of the method, the next step always proceeds to 324.

The bias amplitude of SET/RESET is tuned accordingly at steps 328 and 330 if either of the oscillation or monotone counters reaches their respective maximum values. On the other hand, if at steps 322 and 326, it is determined that the oscillation or monotone counters have not reached to their respective maximum values, the method returns back to step 300 to repeat the programming using the previously used bias amplitudes. If the number of SET or RESET operations applied to the devices exceeds the maximum setting threshold as determined at step 316, the write program would stop and corresponding target resistance state is labeled as “Fail”. Otherwise, the measured Iₙ of the device is determined to be within the tolerated write margin at step 302 and programming is deemed a success to end the programming algorithm. If desired, an optional electrical annealing algorithm is executed to improve retention of the programmed state of the device. This optional electrical annealing algorithm is described later.

Read current sampled at −0.2 V is used to distinguish different resistance states and the current gap between neighboring state is set as 1 μA (5 μS conductance gap). To tighten the distribution of resistance states, write margin (Iₙ−I_{target}) is limited to 200 nA to minimize the influence of random telegraph noise (RTN) and fast relaxation after writing. This write margin was selected for the present embodiments, but different write margins can be selected based on the device used and desired tolerance to the aforementioned noise.

The SAW algorithm of the present embodiment has been applied to over 20 devices to evaluate the capability of multi-level programming. The results show that the algorithm has achieved 4-bit encoding of the fabricated devices. Distribution and cumulative probability of resistance state across devices are shown in FIG. 16(c, d). In comparison, the conventional write-verify algorithm (write time for RESET fixed at 1 μs, two state flags enabled during programming) is also applied to the same devices for 4-bit encoding. It consumes more than twice total write time due to the time wasted on HRS encoding (FIG. 16(b)). If taking the total verify time into consideration, our proposed SAW algorithm consumes only ¼ of the total programming time in comparison to the conventional write-verify incremental step pulse programming algorithm.

The SAW algorithm of the present embodiment can be adapted for use in embedded memory, and more specifically in microcontroller (MCU) for cache or storage. In combination with the dual volatile and non-volatile device embodiment, the proposed multi-level programming algorithm for RRAM enables RRAM devices to work in multi-bit per cell mode, which would increase the memory storage density without extra fabrication overhead. This would lower down the average cost per bit. The reduction in program time means faster operation and less energy consumption. Furthermore, adoption of RRAM in MCU only requires one extra lithography mask in CMOS fabrication process, therefore the fabrication cost impacts are negligible.

The SAW algorithm of the present embodiment can be adapted for use in Al accelerator based on Compute-In-Memory, and provides the advantages of energy efficiency. RRAM based Compute-In-Memory (CIM) Al accelerator consumes less than 1/10 of the energy compared to ASIC based chip of the same performance. Current RRAM based CIM accelerator is built with RRAM storing single bit information. The algorithm of the present embodiment will enable RRAM devices to work in multi-bit per cell mode (>4 bit/cell with in-house fabricated devices, and >10-bit projected for commercial devices) at faster programming speed and less energy consumption, which would increase the computation capacity for RRAM based CIM chip. RRAM based Al accelerator eliminates the need for high-cost on-chip memory like SRAM or HBM.

The SAW algorithm of the present embodiment can be adapted for use in Compute-in-memory, where a non-von-Neumann architecture bypasses the energy and bandwidth limitations in classical computation.

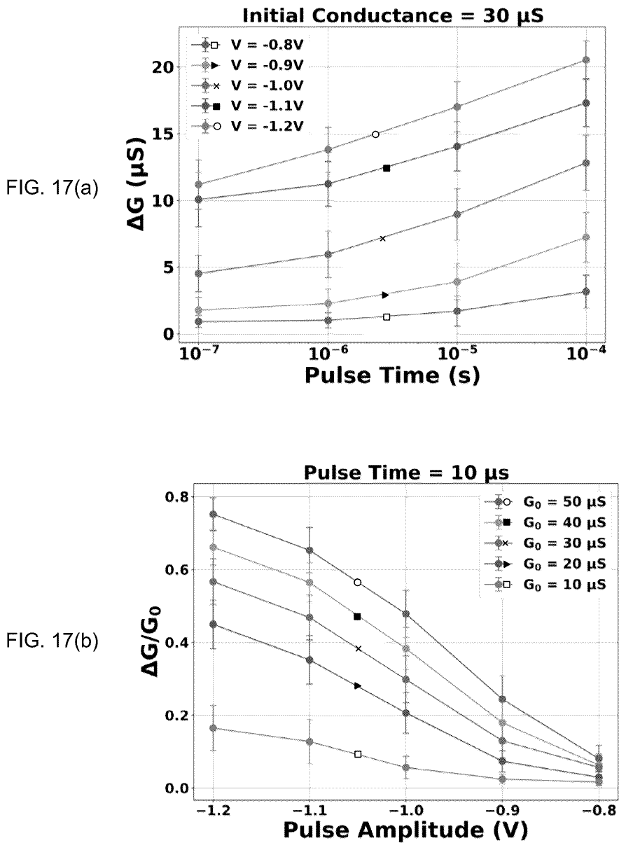

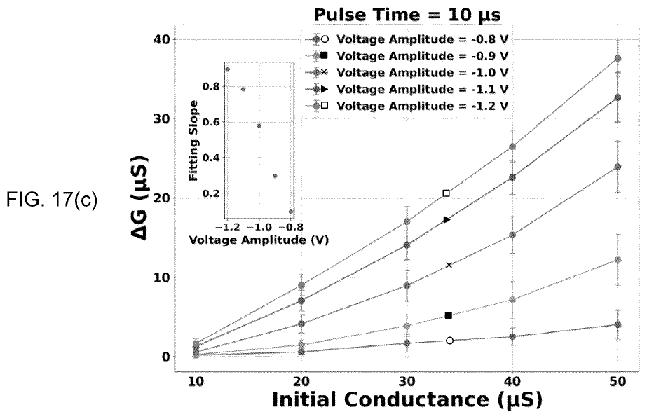

Incremental step pulse programming (ISPP) is a known programming algorithm in the art which could be used for the presently described devices. Another known technique in the art is range dependent tuning. An alternate SAW algorithm which adopts aspects of both ISPP and range dependent tuning is shown in FIG. 17(a), FIG. 17(b) and FIG. 17(c). This alternate algorithm also aims to minimize the write-verify steps, and another challenge to multibit programming of RRAM, the fast relaxation (<1 s) of the conductance state after programming which remains an issue to be solved. In experiments, fast relaxation after multibit programming was characterized, showing conductance state dependence and write direction dependence. The results indicate that RESET is preferred as the termination write direction to mitigate fast relaxation. However, simply applying this strategy to ISPP would lead to an excessive increase in programming time due to the higher probability of overshoot in RESET, leading to repeated writing between SET and RESET. The overshoot of RESET is mainly due to the parameter-tuning nature of the ISPP-like strategy: the amplitude of bias voltage would keep increasing if the target range has not been reached. The range dependent tuning, on the other hand, depends on SET writing for coarse tuning, which is not favored due to fast relaxation.

To explore the possibility of minimizing the overshoot of RESET, the conductance modulation of RESET for different conductance states is characterized by varying the pulse amplitude, pulse duration, and initial conductance states. The observed state dependence of conductance modulation shows that the voltage amplitude needs to be varied based on the conductance difference to avoid overshoot. Apart from that, while voltage amplitude tends to produce exponential conductance change, making it suitable for coarse tuning, the observed logarithmic time dependence is found to be more effective in conductance fine-tuning. Based on these findings, the advantages of ISPP and range-dependent tuning are combined to yield the present state-aware multibit write algorithm embodiment as follows.

1) The voltage amplitude of SET is tuned using the modified ISPP strategy, and two status flags are introduced to provide better tuning of parameters.

2) The parameter tuning of RESET includes coarse tuning, which calculates the voltage amplitude using its conductance state dependence nature, and fine-tuning, which calculates the pulse time needed based on the observed logarithmic time dependence.

Experiments using 4-bit encoding was conducted on fabricated TiOx resistive switching devices, where the algorithm of the present embodiment achieves >2.4× reduction in programming cycles and >2.2× reduction in RESET time.

To examine the conductance modulation of RESET, devices are first programmed to a certain conductance state, and then, a RESET pulse is applied, followed by a read pulse to evaluate the conductance change. Various combinations of initial conductance states, pulse voltage amplitudes, and pulse time of RESET are applied. The initial conductance states are ranged from 10 to 50 μS with step size being 10 μS, the voltage amplitudes are ranged from −0.8 to −1.2 V with step size being 0.1 V, and the pulse time is ranged from 100 ns to 100 μS for each order of magnitude. Measurements were conducted on over 30 devices.

The average conductance change versus pulse time is plotted in FIG. 17(a) where the initial conductance state before RESET is 30 μS, showing a logarithmic time dependence of the conductance change: ΔG∝log(t/t′), and it should also be noted that the amplitude of the conductance change is dependent on the voltage applied. As shown in FIG. 17(b), there exists a linear relationship between the ratio of conductance change and the applied voltage amplitude. A similar linear relationship is also observed when comparing the amplitude of conductance change with the initial conductance state [see FIG. 17(c)], and the fitting slope of the linear dependence also shows a linear dependence on applied voltage [k∝(V−V₀)]. The relationship between ΔG, G₀, and V can be generalized to: (ΔG/G₀)∝(V−V₀). In FIG. 17(c), the inset figure shows the fitting slope versus the voltage amplitude.

The results indicate that the conductance change before and after RESET not only depends on the RESET voltage amplitude and time but also on the initial conductance state. If the current conductance state (G₀) and target conductance state are known, the required voltage amplitude can be estimated based on the linear relationship mentioned above. Following this strategy, the pulse time can also be estimated based on the previous RESET operations applied to the devices. Similar dependence on voltage amplitude and pulse time of RESET have also been observed on known HfO₂₋ and TaOₓ based RRAM devices, indicating that this strategy can be generalized to other metal oxide-based RRAM technologies.

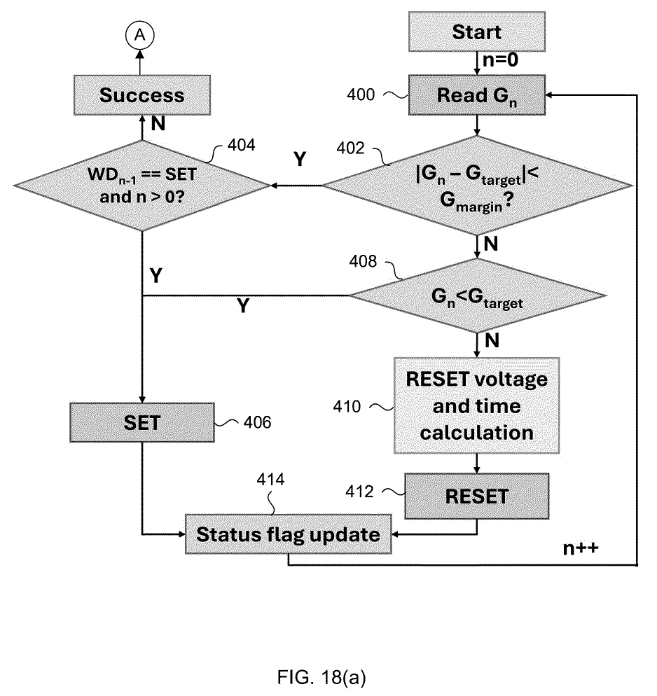

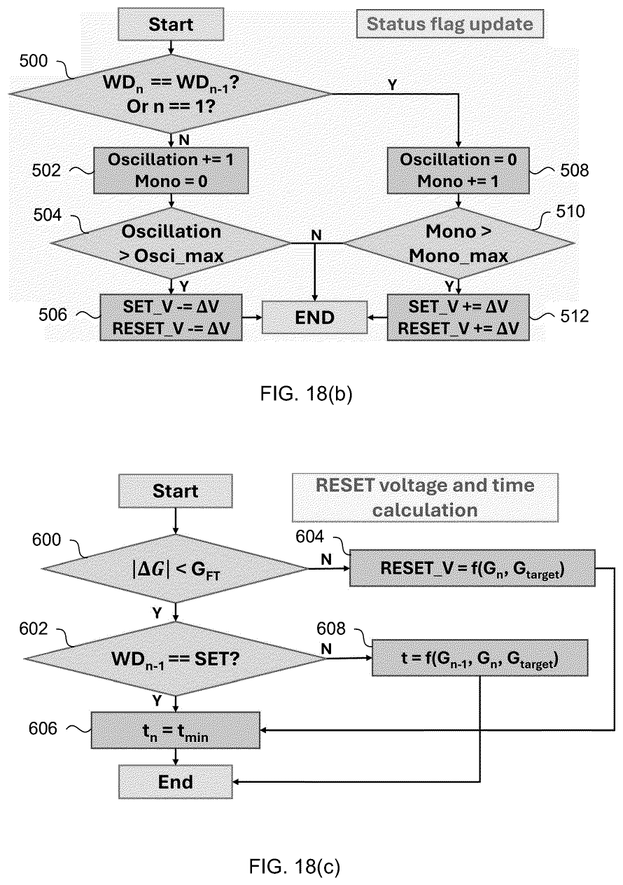

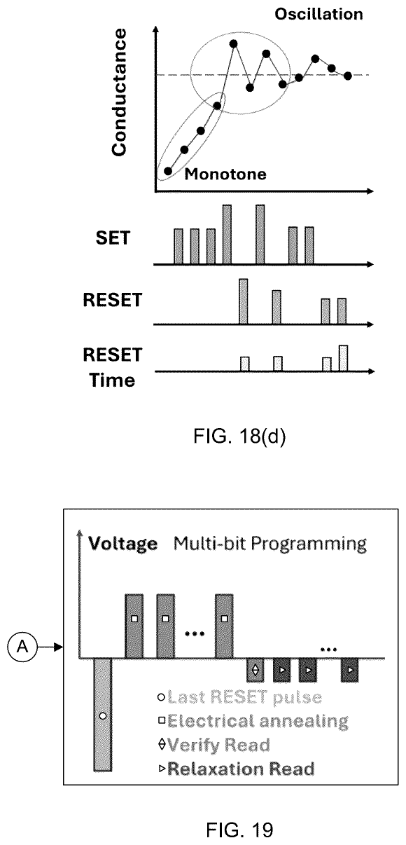

The present state-aware multibit write algorithm embodiment is shown as flow charts in FIG. 18(a), FIG. 18(b) and FIG. 18(c). The algorithm is composed of three modules.

1) Main Body [See FIG. 18(a)]: The main body follows the design of ISPP but takes the mitigation of fast relaxation into consideration. The programming loop starts with a read operation at step 400, followed by a determination of the writing direction (WD) at 402 by comparing the absolute value difference between the read conductance state and a predetermined target value being less than a target margin. If the read conductance state (Gn) is within the target margin the method proceeds to step 404, which determines if the previous cycle was terminated with an SET operation. If yes, it is further SET to a higher conductance state in the next programming cycle at step 406. If at 404 the previous write direction is not SET and the current write cycle is at least 1, this means the programming is successful, ended on a RESET, and the method ends.

Returning to step 402, if Gn is not within the margin then the method proceeds to step 408 to determine if Gn is still less than the predetermined target value. If not then a RESET is needed, the writing parameters for RESET are output from the RESET parameter calculation module at step 410, and a RESET operation is executed at 412. The method of the RESET parameter calculation module is shown in FIG. 18(c).

After the SET or RESET operation (406 or 412), the status flag update module is executed at 414 to update the status flags and tune the writing parameters accordingly. Then the method loops back to start the cycle again at step 400. The writing is marked as a success only when the conductance state is within the target margin as determined at step 402, and the last WD is RESET as determined at step 404. The method of the status flag update module is shown in FIG. 18(b).

2) Status Flag Update Module [See FIG. 18(b)]: The method of this module is designed to fine-tune the programming parameters (mainly for SET operations). It consists of two status flags: oscillation and monotone. Oscillation is defined as when the read current oscillates around the target current with SET/RESET pairs applied to the devices, indicating that the bias amplitude of either SET or RESET is too large to fine-tune the resistance state. Monotone is defined as when the read current consistently stays above or below the target value, which indicates that the bias amplitude of the applied SET (or RESET) pulse is insufficient to trigger the resistance change. The bias amplitude of SET/RESET is tuned accordingly if either of the status flags is triggered.

The flow chart shown in FIG. 18(b) is executed in step 414 of FIG. 18(a). From either 406 or 412 of FIG. 18(a), the method begins with a determination at 500 if the current write direction is the same or not as the previous write direction. If this is the first write cycle (n==1) then the next step always proceeds to 508. For subsequent write cycles, if the current write direction is not the same as the previous write direction, then the method proceeds to step 502 where an oscillation counter is incremented. A determination is made at 504 to check if the oscillation counter has exceeded a maximum value. If yes, then an adjustment is made to reduce the SET and RESET voltage levels by some predetermined level at 506. Otherwise, the method ends and no changes are made to the SET and RESET voltage levels.

Returning to step 500, if the current write direction is not the same as the previous write direction, the method proceeds to step 508 where a monotone counter is incremented. A determination is made at 510 to check if the monotone counter has exceeded a maximum value. If yes, then an adjustment is made to increase the SET and RESET voltage levels by some predetermined level at 512. Otherwise, the method ends and no changes are made to the SET and RESET voltage levels.

3) RESET Voltage and Time Calculation Module [See FIG. 18(c)]: This module calculates the optimal RESET parameters based on the linear relationships observed in the conductance modulation study. The method of FIG. 18(c) is executed in step 410 of FIG. 18(a). Starting at 600, for each RESET writing, if the conductance difference, defined as ΔG=|G_{target}−Gₙ|, is within the predefined fine-tune conductance range (G_{FT}) the method proceeds to step 602. A determination is made at 602 to see if the previous write direction was SET, and if so the voltage remains unchanged. Returning to step 600, If ΔG exceeds G_{FT}, a coarse adjustment is needed, the voltage amplitude of RESET is calculated based on the linear relationship between (ΔG/G₀) and V at step 604. In both cases where the previous write direction was SET and AG exceeds G_{FT}, the pulse time is set as tₘᵢₙ at step 606. If ΔG is within G_{FT} (from 600) and the previous write direction is RESET (at 602), fine adjustment is needed, the new pulse time is calculated at 608 based on the observed logarithmic dependence of the pulse time.

An example of the proposed algorithm is shown in FIG. 18(d), the monotone and oscillation flags are triggered in the presented examples, and the tuning of RESET voltage amplitude and the RESET pulse time based on the state-dependent calculation is also illustrated. The bar height of SET/RESET (RESET time) represents the voltage amplitude (pulse time) applied. The triggering of monotone and oscillation status flags is illustrated in the conductance change plot.

To evaluate the performance of the state-aware multibit write algorithm of the present embodiment, benchmarks were conducted using TiOₓ devices with initial conductance states randomly assigned between 10 and 50 μS. The ISPP algorithm used in this comparison shares the design of the algorithm but without the RESET parameter calculation module. The pulse time of RESET in ISPP is fixed at 1 μS. The shared parameters between ISPP and this proposed algorithm are listed in Table 2 below.

TABLE 2

| | | | | | |
|---|---|---|---|---|---|
| RESET start voltage | −1 | V | Minimum conductance | 10 | μs |
| | | | state | | |
| RESET voltage step | 0.05 | V | Maximum conductance | 50 | μs |
| | | | state | | |
| SET start voltage | 0.9 | V | Conductance step | 2.5 | μs |
| SET voltage step | 0.05 | V | Conductance margin | 0.5 | μs |

| | | | | |
|---|---|---|---|---|
| SET pulse time | 10 | μs | Oscillation count max | 3 |
| Read voltage | 0.2 | V | Monotone count max | 4 |

| | |
|---|---|
| Maximum writing trials | 300 |

For the RESET parameter calculation module in this algorithm: the fine-tune conductance margin (G_{FT}) is set as 2.5 μS; the fitting equation used for RESET voltage calculation is:

$$\frac{\vert {G}_{n} - {G}_{target} \vert}{{G}_{n}} = {k}_{υ} * ( {V}_{RESET} - {V}_{min} )$$

where kᵥ=−2 V⁻¹ and Vmin=−0.6 V based on the measurements mentioned in previous section; the fitting equation used for the RESET time calculation is:

$$Δ G = {k}_{t} * log ( t ) + b$$

The fitting slope kt can be calculated from the last RESET writing:

$${k}_{t} = \frac{{G}_{n} - {G}_{n - 1}}{log ( {t}_{n - 1} + {t}_{h} ) - log ( {t}_{h} )}$$

where Gₙ is current conductance state, Gₙ₋₁ is the conductance state before last RESET operation, and tₙ₋₁ is the pulse time of last RESET operation. tₕ is set to 100 ns, which assumes that no change in conductance would be expected within this time frame for each writing. The calculated time for RESET would be:

$${t}_{n} = ( {e}^{\frac{{G}_{n} - {G}_{target}}{{k}_{t}}} - 1 ) * {t}_{h}$$

If the WD before RESET is SET, the pulse time of RESET is set to tₘᵢₙ=100 ns. To eliminate the influence of read noise and writing variation, the moving average of the slope kt is used for the calculation of RESET time, and the maximum pulse time applied is capped at 10 μS.

The SAW algorithm of the present embodiment outperforms the ISPP due to its state-aware calculation of RESET parameters, which is implemented using a parameter analyzer and a PC. The parameter analyzer samples the conductance state (current) with a 14-bit analog-to-digital converter (ADC), outputs the voltage waveform through a 12-bit digital-to analog converter (DAC), and stores all data in a 32-bit floating-point format, all of which are resource-intensive in real hardware implementations. To assess the influence of ADC/DAC quantization on performance and evaluate hardware overhead, consider an example multibit programming module comprising.

1) ADC for Current Sampling: A 9-bit ADC with a quantization resolution of 50 nA and a measurement range from 50 nA to 20 μA.

2) DAC for Voltage Output: A 6-bit DAC with a quantization resolution of 0.01 V and an output range from −0.6 to −1.2 V.

3) Pulse Time Control: Managed by an RISC-V CPU controlling the number of clock cycles, with a clock period of 20 ns and an output range from 20 ns to 10 μS.

The quantized version of the SAW algorithm of the present embodiment is implemented by applying the ceiling function to all parameters (sampled current, pulse voltage amplitude, and pulse time) during programming. The performance of the quantized algorithm is evaluated using the same performance metrics as described above, and the results indicate that similar performance is achieved with ADC/DAC quantization loss taken into consideration. This demonstrates that the presently described SAW algorithm maintains its advantages even with limited hardware precision, requiring no extra hardware overhead. Therefore, it is practical for real-world implementations and can be efficiently integrated into existing systems.

Fast relaxation after programming is found to be depending on the write direction, with RESET preferred as the termination WD to minimize the influence of fast relaxation. The observed conductance state dependence of voltage amplitude and the logarithmic dependence of pulse time have been proposed to accelerate the multibit programming. Based on these findings, the state-aware multibit write algorithm of the present embodiment accelerates multibit programming by incorporating state-dependent calculations of RESET parameters. Unlike ISPP, the SAW algorithm adjusts the RESET parameters based on the current conductance state, target conductance state, and conductance difference. This precise parameter selection effectively eliminates oscillations between SET and RESET operations.

Experimental validation using 4-bit encoding and designed bit patterns demonstrates that the SAW algorithm outperforms the ISPP approach, achieving over 2.4 times reduction in programming steps and over 2.2 times reduction in total RESET time. Furthermore, we assessed the influence of ADC/DAC quantization loss on the proposed algorithm, showing that it performs effectively without requiring additional hardware overhead. The state-aware multibit write algorithm of the present embodiment provides a practical and efficient solution for enhancing the performance of RRAM devices in high-density memory applications. By addressing the challenges of fast relaxation and optimizing the RESET process, this algorithm contributes to the advancement of reliable and efficient nonvolatile memory technologies.

While the previously described SAW programming algorithms of the present embodiments improves upon existing algorithms for RRAM devices, there still remains an issue with such programmed RRAM devices.

The stability of the conductance states is often compromised during the programming process. The stability of the conductance states is important for RRAM based CIM systems, as the state drift of the conductance states would lead to the degradation of the classification accuracy over time. The drift of the conductance states includes short-term fast relaxation loss and long term retention loss. The fast relaxation loss is found to be dependent on the programming directions and can be mitigated by having RESET as the last programming step, which has been set as one condition of the SAW algorithm of FIG. 18(a). The retention loss, however, remains a challenge for the multi-bit programming of RRAM devices.

The retention loss of the conductance states after multi-bit programming was investigated. The retention loss was found to be state dependent, with the larger conductance states showing more severe retention loss. The retention loss is also observed to be unidirectional, all the states are shifted towards the lower conductance states (higher resistance states). The observations indicate that the retention loss is likely related to the oxygen vacancy, especially the dangling ones due to fast multi-bit programming, around the conducting filament region.

According to another embodiment, an electrical annealing method is used to mitigate the retention loss. The electrical annealing is based on the thermal effect induced by sub-SET voltage pulses (voltage amplitude smaller than that of SET operation), which can help speed up the settlement of loose oxygen atoms and vacancies to their local equilibrium positions without triggering further conductance change. This strategy is analogous to the concept of rapid thermal annealing, capable of optimizing the local atomic environment but not triggering any long range migrations, therefore it is expected to be generically applicable to other filamentary memristors. In experiments with in-house fabricated devices, the electrical annealing is found to be effective in mitigating the retention loss, with the time constant of the retention loss increased by 2.5× after electrical annealing. The influence of retention loss on classification accuracy is also evaluated by CIM simulation, and the electrical annealing helps to elongate the refresh period by 3×.

The fabricated devices are programmed to 4 different conductance states (10 μS, 17.5 μS, 25 μS and 32.5 μS) using the previously described state aware multi-bit programming algorithm of FIG. 18(a). Minor decay of conductance states is observed during the fast relaxation test, while a significant retention loss is observed after 10000 s. The retention loss is found to be state dependent, with the larger conductance states showing more severe retention loss. The retention loss is also found to be unidirectional, all the states are shifted towards the lower conductance states (higher resistance states).

Similar to the SET induced fast relaxation decay, the monotonic drift and state dependence of the retention loss indicates that the retention loss is related to the oxygen vacancy around the conducting filament region, especially the dangling ones. The spontaneous oxidation of the Ti dangling bonds around oxygen vacancies is thermally activated, which leads to the retention loss. Since the process is thermally driven, thermal annealing could significantly accelerate the retention loss, particularly in the initial stages, where the decay rate is fastest due to the exponential time dependence of conductance changes. By expediting this early stage relaxation, annealing leads to a more stable conductance state, making subsequent readings more reliable. However, annealing is usually performed at elevated temperature, which is not practical for real applications.

Therefore, an electrical annealing method according to the present embodiment based on voltage pulses is proposed to relieve the retention loss. The sub-SET voltage pulses locally heats the filament region to mimic thermal effects without global temperature increases. As shown in FIG. 19, these pulses are applied after the final RESET pulse in the programming loop of FIG. 18(a). Therefore, the electrical annealing method shown here can be an optional final step in FIG. 18(a) after programming is deemed successful. This electrical annealing method can also be an optional final step for the SAW algorithm shown in FIG. 15. In both FIGS. 15 and 18(a), a lead bubble “A” indicates the method can proceed to the corresponding lead bubble “A” in FIG. 19. It is noted the last RESET pulse shown in FIG. 19 is not executed for the method of FIG. 15. This method accelerates the equilibration between Ti dangling bonds and their re-oxidation early on, stabilizing conductance faster while minimizing uncontrollable conductance changes afterwards.

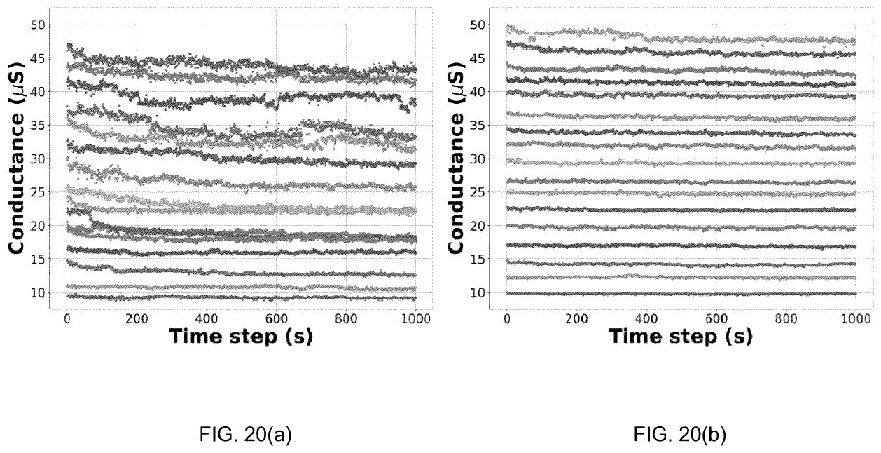

One specific set of parameters for the presently described electrical annealing method embodiment is as follows. The sub-SET voltage pulse width is set to 10 μs, the voltage amplitude (0.4 V˜0.75 V) and the number of sub-SET pulses (10˜100) are varied. The results show that the retention loss can be greatly mitigated when the voltage amplitude is set around 0.7 V and the number of sub-SET pulses is set to 10 (total biasing time=100 μs). The 4-bit retention results without and with electrical annealing are shown in FIGS. 20(a) and 20(b). Electrical annealing significantly mitigates retention loss, with conductance states showing minimal degradation after 1000 seconds. Curve fitting with exponential decay function,

$$( \frac{C ( t )}{C ( 0 )} = exp ( - \frac{t}{{t}_{0}} )$$

where t₀ is the time constant is applied to the retention results, and the fitting results show that the time constant of the retention loss is increased by around 2.5× after electrical annealing. The electrical annealing method parameters can be fixed for electrical annealing a device regardless of the conductance state written to it. However, persons skilled in the art will understand that different sets of parameters can be customized to anneal each state to further improve retention loss for each specific state.

While the actual mechanisms causing retention loss have not yet been analyzed, for example by detailed physical analysis and characterization of the programmed memristor devices, a sound understanding of fundamental semiconductor material principles can provide a reasonable hypothesis. It is theorized that the retention loss is mainly caused by the diffusion of the dangling oxygen vacancies around the formed conducting filament region. The diffusion process is thermally activated, and sub-SET voltage pulses of the previously described electrical annealing method induce localized Joule heating that accelerates vacancy migration. Furthermore, the electric field direction of these pulses can influence the natural diffusion path of oxygen vacancies, thereby suppressing retention loss. Through the electrical annealing method, the combined thermal and field effects are theorized to help stabilize dangling oxygen vacancies, resulting in more reliable verify readings and improved accuracy in programming the conductance states. Those skilled in the art will appreciate that this area of study is complex, and further detailed analysis will reveal new information about the issues influencing retention in specific memristor devices as well as the full effects of electrical annealing. Testing on actual devices has demonstrated the improvement to retention by the described electrical annealing method embodiment.

In summary, a lithium (Li) imbued TiOx memristor device that exhibits synapse-like short-term plasticity (STP) behavior without requiring a forming process beforehand or a compliance current during switching has been developed. A solid-state electrolyte lithium phosphorus oxynitride (LiPON) behaves as the ion source, and the embedding and releasing of Li ions inside the cathodic like TiOx renders volatile conductance responses from the device and offers a natural platform for hardware simulating neuron functionalities. Besides, these devices possess high uniformity and great endurance as no conductive filaments are present. Different short-term pulse-based phenomena, including paired pulse facilitation (PPF), post-tetanic potentiation (PTP), and spike rate-dependent plasticity (SRDP), were observed with unique self-relaxation characteristics. Based on the voltage excitation period, the timescale of the volatile memory can be tuned. Temperature measurement reveals the ion displacement-induced conductance channels become frozen below 220K. In addition, the volatile analog devices can be configured into non-volatile memory units with multibit storage capabilities after an electroforming process. Therefore, on the same platform, volatile units can be configured as nonlinear dynamic reservoirs for performing neuromorphic training and the non-volatile units can be configured as the weight storage layer. The voice recognition experiment with the tunable time constant relationship obtained 94.4% accuracy with a minimal training dataset. Thus, this ion-imbued platform can effectively process and update temporal information for reservoir and neuromorphic computing paradigms.

State aware programming algorithm embodiments have been described to minimize programming times of RRAM devices programmable to have any one of multiple states in a non-volatile mode of operation. An optional electrical annealing method is employed to further improve retention of the programmed states.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. Thes machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art. The scope of the claims should not be limited by the particular embodiments set forth herein, but should be construed in a manner consistent with the specification as a whole.

1. A resistive memory device configurable to operate in volatile or non-volatile modes, comprising:
a first electrode;
a second electrode; and,
an active switching bilayer formed of a first variable conductive layer and a second variable conductive layer ionically coupled together and electrically coupled between the first electrode and the second electrode, wherein
in a volatile mode of operation the first variable conductive layer transfers ions into the second variable conductive layer to change electrical conductivity in response to at least one applied voltage sweep of a first polarity across the first electrode and the second electrode, and receives ions from the second variable conductive layer to change back electrical conductivity by at least one of naturally relaxing ions back and in response to at least one applied voltage sweep of a second polarity across the first electrode and the second electrode; and
in a non-volatile mode of operation conductive filaments are formed in the bilayer to set a low resistance state (LRS) in response to application of a first voltage across the first and second electrodes, and the conductive filaments are ruptured to set a high resistance state (HRS) in response to a second voltage in the same or opposite in polarity to the first voltage.

2. The resistive memory device of claim 1, wherein the bilayer is composed of ion-active metal and metalloid compounds.

3. The resistive memory device of claim 1, wherein the ion distribution is adjustable in response to external electric fields and intrinsic thermodynamics to correspondingly change the bilayer conductivity.

4. (canceled)

5. The resistive memory device of claim 1, wherein the active switching bilayer electrical conductivity changes in magnitude and at a higher rate in response to a higher maximum amplitude of the applied voltage sweep of the first polarity, and the electrical conductivity changes oppositely in magnitude and at a higher rate in response to a higher maximum amplitude of the applied voltage sweep of the second polarity.

6. The resistive memory device of claim 1, wherein the active switching bilayer electrical conductivity changes in magnitude and at a higher rate in response to at least one of a higher number of applied voltage sweeps and a higher maximum amplitude of each of the applied voltage sweeps of the first polarity, and the electrical conductivity changes oppositely in magnitude and at a higher rate in response to at least one of a higher number of applied voltage sweeps and a higher maximum amplitude of each of the applied voltage sweeps of the second polarity.

7. The resistive memory device of claim 1, wherein the active switching bilayer has a natural relaxation rate whereby ions injected into the second variable conductive layer migrate back into the first variable conductive layer to eventually settle at a predetermined electrical conductive state after a period of time.

8. The resistive memory device of claim 7, further including an ion relaxation inhibitor configured to inhibit ion relaxation back into the first variable conductive layer by setting a desired relaxation rate of the active switching bilayer.

9. The resistive memory device of claim 8, wherein the ion relaxation inhibitor includes an ion diffusion barrier.

10. The resistive memory device of claim 8, wherein the ion relaxation inhibitor includes an ion channel constriction to inhibit ion relaxation back into the first variable conductive layer.

11. The resistive memory device of claim 10, wherein the ion channel constriction includes a pinhole.

12. The resistive memory device of claim 10, wherein the ion channel constriction includes nanowires.

13. The resistive memory device of claim 10, wherein the ion channel constriction includes nanotubes.

14. The resistive memory device of claim 10, wherein the ion channel constriction includes structured materials with 1D or 2D ionic conduction channels.

15. The resistive memory device of claim 1, wherein the active switching bilayer is configurable to have another intermediate resistive state with a resistance different from the HRS and LRS, in response to a third voltage pulse with selected amplitude and time.

16. The resistive memory device of claim 15, wherein the LRS, HRS and the other high resistive state represent first, second and third logic states.

17. The resistive memory device of claim 1, wherein the active switching bilayer is configurable to have multiple resistive states between the HRS and the LRS, each of the multiple resistive states being set in response to different respective voltage pulse levels and durations.

18. Use of a resistive memory device as recited in claim 7 in security applications to store sensitive data that returns to the HRS after a predetermined period of time.

19. Use of a resistive memory device as recited in claim 1 as a non-volatile memory in a compute-in-memory (CIM) array, where two resistive memory devices of claim 1 are arranged as an accessible unit cell storing multiple bits of data.

20. Use of a configurable array of memory devices, where each individual device can be formed on demand into a device as recited in claim 1 or one as in claim 8, rendering a generic platform field-programmable into complex neural networks.
